(19) United States
(12) Patent Application Publication
(10) Pub. No.: US 2026/0164938 A1
(43) Pub. Date: Jun. 11, 2026

(54) DISPLAY DEVICE AND METHOD OF MANUFACTURING THE SAME

(71) Applicant: Samsung Display Co., Ltd., Yongin-si (KR)

(72) Inventors: Seok Hyun LIM, Yongin-si (KR); Eun Ho SONG, Yongin-si (KR); Da Sol JEONG, Yongin-si (KR)

(21) Appl. No.: 19/178,032

(22) Filed: Apr. 14, 2025

(30) Foreign Application Priority Data
Jun. 20, 2024 (KR) 10-2024-0080194
Jul. 10, 2024 (KR) 10-2024-0091119

(51) Int. Cl. H10K 59/122; H10K 59/12

(52) U.S. Cl. CPC H10K 59/122; H10K 59/1201

(57) ABSTRACT

A display device includes a substrate; a pixel circuit layer on the substrate; an anode electrode on the pixel circuit layer; a pixel definition layer on the pixel circuit layer and having an opening that exposes at least a part of the anode electrode; a sacrificial pattern in the opening, between the anode electrode and the pixel definition layer, and overlapping the anode electrode and the pixel definition layer; a light emitting structure on the anode electrode and the pixel definition layer; and a cathode electrode on the light emitting structure, wherein the pixel definition layer includes a first portion that overlaps the anode electrode and does not overlap the sacrificial pattern, a second portion that overlaps the anode electrode and the sacrificial pattern, and a third portion that does not overlap the anode electrode or the sacrificial pattern, and the sacrificial pattern includes a metal material.

### CROSS-REFERENCE TO RELATED APPLICATION

The present application claims priority to and the benefit of Korean Patent Application No. 10-2024-0080194, filed on Jun. 20, 2024, and Korean Patent Application No. 10-2024-0091119, filed on Jul. 10, 2024, in the Korean Intellectual Property Office, the entire disclosure of each of which is incorporated herein by reference.

### BACKGROUND

### 1. Field

Embodiments of the present disclosure relate to a display device and a method of manufacturing the display device.

### 2. Description of the Related Art

With the advancement (development) of information technology, the significance (importance) of display devices, which serve as the interface (connection media) between users and information, has increased. Accordingly, the utilization of display devices, such as liquid crystal display devices (LCDs) and organic light emitting display devices, is on the rise.

For instance, an organic light emitting diode (OLED) is an active light emitting display device that may have the advantages such as a wide viewing angle, excellent or suitable contrast, low voltage operation, a lightweight and thin design (thin body), and/or fast response speed. These desired features makes OLEDs (or organic light emitting display devices) attractive as a next-generation display devices.

The above information disclosed in this Background section is only for enhancement of understanding of the background of the disclosure and therefore it may contain information that does not constitute prior art.

### SUMMARY

Aspects of embodiments of the present disclosure are directed to a display device with improved reliability and a method of manufacturing the display device. For example, the display device may effectively improve a lateral leakage phenomenon, in which a current flows laterally between neighboring sub-pixels, by disposing, on an anode electrode, a sacrificial pattern including a metal material. In other words, the display device may effectively mitigate a lateral leakage phenomenon, where current flows laterally between neighboring sub-pixels, by incorporating a sacrificial pattern made of metal material on the anode electrode.

Aspects of one or more embodiments of the present disclosure provide a method of manufacturing a display device with improved reliability.

Additional aspects will be set forth in part in the description which follows and, in part, will be apparent from the description, or may be learned by practice of the presented embodiments of the disclosure.

One or more embodiments of the present disclosure provide a display device including: a substrate; a pixel circuit layer on the substrate; an anode electrode on the pixel circuit layer; a pixel definition layer on the pixel circuit layer and having an opening that exposes at least a part of the anode electrode; a sacrificial pattern in the opening, between the anode electrode and the pixel definition layer, and overlapping the anode electrode and the pixel definition layer; a light emitting structure on the anode electrode and the pixel definition layer; and a cathode electrode on the light emitting structure, wherein the pixel definition layer includes a first portion that overlaps the anode electrode and does not overlap the sacrificial pattern, a second portion that overlaps the anode electrode and the sacrificial pattern, and a third portion that does not overlap the anode electrode or the sacrificial pattern, and the sacrificial pattern includes a metal material.

In one or more embodiments, the sacrificial pattern may include aluminum (Al).

In one or more embodiments, the light emitting structure may be partially disconnected in a region adjacent to the first portion of the pixel definition layer.

In one or more embodiments, the first portion of the pixel definition layer and a side surface of the sacrificial pattern together may have an undercut shape.

In one or more embodiments, the undercut shape may be provided, on the anode electrode, by the first portion protruding more than (e.g., extending beyond) the sacrificial pattern.

In one or more embodiments, the sacrificial pattern may be between the second portion and the anode electrode.

In one or more embodiments, the first portion may be separated by an interval from the anode electrode.

In one or more embodiments, the sacrificial pattern may have a first width, the first portion may have a second width, the second portion may have a third width, and a sum of the second width and the third width may be greater than the first width.

In one or more embodiments, the light emitting structure may include light emitting units that are sequentially stacked and a charge generation layer between the light emitting units, and the light emitting unit adjacent to the anode electrode among the light emitting units may be partially disconnected from the charge generation layer.

In one or more embodiments, the light emitting structure may include a hole injection layer on the anode electrode, a hole transfer layer on the hole injection layer, a light emitting layer on the hole transfer layer, an electron transfer layer on the light emitting layer, and an electron injection layer on the electron transfer layer, and wherein the hole injection layer may be partially disconnected.

In one or more embodiments, the anode electrode may have an upper surface adjacent to the light emitting structure, and the sacrificial pattern may be along an edge (e.g., outer edge) of the anode electrode on the upper surface.

In one or more embodiments, the light emitting structure may be in contact with the upper surface of the anode electrode.

In one or more embodiments, the pixel definition layer may further include a trench in the third portion and dented toward the substrate, and the trench may be around (e.g., surround) the anode electrode.

In one or more embodiments, the pixel definition layer may include a first insulating layer including the first portion, the second portion and the third portion, a second insulating layer on the first insulating layer, and a third insulating layer on the second insulating layer, and wherein the third insulating layer may have a width greater than a width of the second insulating layer.

One or more embodiments of the present disclosure provide a method of manufacturing a display device, the method including: forming a pixel circuit layer on a substrate; forming an anode electrode on the pixel circuit layer; forming a metal layer on the anode electrode; forming, on the pixel circuit layer, a pixel definition layer having an opening that exposes a part of the metal layer; removing an exposed part of the metal layer and leaving, as a sacrificial pattern, another part of the metal layer which is not exposed, wherein the removing of the exposed part of the metal layer exposes at least a part of the anode electrode; and forming a light emitting structure over the anode electrode and the pixel definition layer, wherein the pixel definition layer includes a first portion that overlaps the anode electrode and does not overlap the sacrificial pattern, a second portion that overlaps the anode electrode and the sacrificial pattern, and a third portion that does not overlap the anode electrode or the sacrificial pattern.

In one or more embodiments, in the removing of the exposed part of the metal layer, the metal layer may be wet-etched to form the first portion of the pixel definition layer protruding more than (e.g., extending beyond) the sacrificial pattern.

In one or more embodiments, the light emitting structure may be partially disconnected in a region adjacent to the first portion of the pixel definition layer.

### BRIEF DESCRIPTION OF THE DRAWINGS

FIG. 1 is a block diagram illustrating a display device according to one or more embodiments of the present disclosure.

FIG. 2 is a block diagram illustrating one of sub-pixels of FIG. 1, according to one or more embodiments of the present disclosure.

FIG. 3 is a circuit diagram illustrating the sub-pixel of FIG. 2, according to one or more embodiments of the present disclosure.

FIG. 4 is a plan view illustrating a display panel of FIG. 1, according to one or more embodiments of the present disclosure.

FIG. 5 is an exploded perspective view illustrating a part of the display panel of FIG. 4, according to one or more embodiments of the present disclosure.

FIG. 6 is a plan view illustrating one of pixels of FIG. 5, according to one or more embodiments of the present disclosure.

FIG. 7 is a cross-sectional view taken along the line I-I′ of FIG. 6, according to one or more embodiments of the present disclosure.

FIG. 8 is an enlarged view illustrating a region A of FIG. 7, according to one or more embodiments of the present disclosure.

FIG. 9 is an enlarged view illustrating a region B of FIG. 8, according to one or more embodiments of the present disclosure.

FIG. 10 is a cross-sectional view illustrating a part of a light emitting structure included in any one of first to third light emitting elements of FIG. 7, according to one or more embodiments of the present disclosure.

FIG. 11 is a cross-sectional view illustrating a part of the light emitting structure included in any one of the first to third light emitting elements of FIG. 7, according to one or more embodiments of the present disclosure.

FIG. 12 is a plan view illustrating a pixel according to one or more embodiments of the present disclosure.

FIG. 13 is a plan view illustrating a pixel according to one or more embodiments of the present disclosure.

FIG. 14 is a cross-sectional view taken along the line I-I′ of FIG. 6, according to one or more embodiments of the present disclosure.

FIG. 15 is a cross-sectional view taken along the line I-I′ of FIG. 6, according to one or more embodiments of the present disclosure.

FIGS. 16 to 19 are cross-sectional views schematically illustrating a method of manufacturing a display device, according to one or more embodiments of the present disclosure.

FIG. 20 is a block diagram illustrating a display system, according to one or more embodiments of the present disclosure.

FIG. 21 is a perspective view illustrating a head mounted display device as an example of an application of the display system of FIG. 20, according to one or more embodiments of the present disclosure.

FIG. 22 is a view illustrating the head mounted display device of FIG. 21 worn by a user, according to one or more embodiments of the present disclosure.

### DETAILED DESCRIPTION

The present disclosure may be modified in many alternate forms, and thus specific embodiments will be illustrated in the drawings and described in more detail. It should be understood, however, that this is not intended to limit the present disclosure to the particular forms disclosed, but rather, is intended to cover all modifications, equivalents, and alternatives falling within the spirit and scope of the present disclosure.

Hereinafter, example embodiments of the present disclosure will be described in more detail with reference to the accompanying drawings. The present disclosure, however, may be embodied in various different forms, and should not be construed as being limited to only the illustrated embodiments herein. Rather, these embodiments are provided as examples so that this disclosure will be thorough and complete, and will fully convey the aspects and features of the present disclosure to those skilled in the art. Accordingly, processes, elements, and techniques that are not necessary to those having ordinary skill in the art for a complete understanding of the aspects and features of the present disclosure may not be described.

It will be understood that when an element, such as an area, layer, film, region or portion, is referred to as being “on,” “connected to,” or “coupled to” another element, it can be directly on, connected to, or coupled to the other element, or one or more intervening elements may be present. In contrast, when an element or layer is referred to as being “directly on,” “directly connected to”, “directly coupled to”, or “immediately adjacent to” another element or layer, there are no intervening elements or layers present. In addition, it will also be understood that when an element is referred to as being “between” two elements, it can be the only element between the two elements, or one or more intervening elements may also be present.

The terminology used herein is for the purpose of describing particular embodiments only and is not intended to be limiting of the present disclosure. It will be further understood that the terms “comprises,” “comprising,” “includes,” “including,” “have,” and “having,” when used in this specification, specify the presence of the stated features, integers, steps, operations, elements, and/or components, but do not preclude the presence or addition of one or more other features, integers, steps, operations, elements, components, and/or groups thereof.

Unless otherwise apparent from the disclosure, expressions such as “at least one of,” “a plurality of,” “one of,” and other prepositional phrases, when preceding a list of elements, should be understood as including the disjunctive if written as a conjunctive list and vice versa. For example, the expressions “at least one of a, b, or c,” “at least one of a, b, and/or c,” “one selected from the group consisting of a, b, and c,” “at least one selected from among a, b, and c,” “at least one from among a, b, and c,” “one from among a, b, and c”, “at least one of a to c” indicates only a, only b, only c, both a and b, both a and c, both b and c, all of a, b, and c, or variations thereof. As used herein, the term “and/or” includes any and all combinations of one or more of the associated listed items.

It will be understood that, although the terms “first,” “second,” “third,” etc., may be used herein to describe various elements, components, regions, layers and/or sections, these elements, components, regions, layers and/or sections should not be limited by these terms. These terms are used to distinguish one element, component, region, layer or section from another element, component, region, layer or section. Thus, a first element, component, region, layer or section described below could be termed a second element, component, region, layer or section, without departing from the spirit and scope of the present disclosure.

Spatially relative terms, such as “on,” “below,” “lower,” “under,” “above,” “upper,” and the like, may be used herein for ease of explanation to describe one element or feature's relationship to another element(s) or feature(s) as illustrated in the figures. It will be understood that the spatially relative terms are intended to encompass different orientations of the device in use, operation, and/or manufacture, in addition to the orientation depicted in the drawings. For example, if the device in the figures is turned over, elements described as “below” or “beneath” or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly.

Various embodiments are described herein with reference to sectional illustrations that are schematic illustrations of idealized embodiments. As such, variations from the shapes of the illustrations as a result, for example, of manufacturing techniques and/or tolerances, are to be expected. Thus, example embodiments disclosed herein should not be construed as limited to the particular illustrated shapes of regions, but are to include deviations in shapes that result from, for instance, manufacturing. Thus, the regions illustrated in the drawings are schematic in nature and their shapes are not intended to illustrate the actual shape of a region of a device and are not intended to be limiting. In addition, in the drawings, the relative sizes of elements, layers, and regions may be exaggerated for clarity.

Unless otherwise noted, like reference numerals denote like elements throughout the attached drawings and the written description, and thus, duplicative descriptions thereof may not be provided. As used herein, the singular forms “a,” “an” and “the” are intended to include the plural forms as well, unless the context clearly indicates otherwise. As used herein, the terms “use,” “using,” and “used” may be considered synonymous with the terms “utilize,” “utilizing,” and “utilized,” respectively.

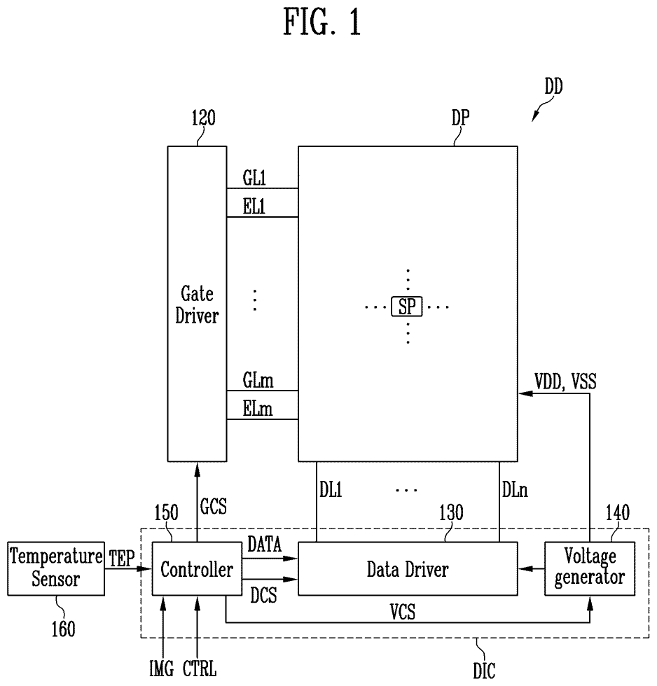

FIG. 1 is a block diagram illustrating a display device according to one or more embodiments of the present disclosure.

Referring to FIG. 1, a display device DD may include a display panel DP, a gate driver 120, a data driver 130, a voltage generator 140, and a controller 150.

The display panel DP may include sub-pixels SP. The sub-pixels SP may be connected to the gate driver 120 through first to m-th gate lines GL1 to GLm. The sub-pixels SP may be connected to the data driver 130 through first to n-th data lines DL1 to DLn.

Each of the sub-pixels SP may include at least one light emitting element configured to generate and/or emit light. Accordingly, each of the sub-pixels SP may be to emit light of a specific color, such as red, green, blue, cyan, magenta, yellow, and/or the like. Two or more sub-pixels among the sub-pixels SP may constitute one pixel PXL. For example, as illustrated in FIG. 1, three sub-pixels may constitute one pixel PXL.

The gate driver 120 may be connected to the sub-pixels SP arranged in a row direction through the first to m-th gate lines GL1 to GLm. The gate driver 120 may output gate signals to the first to m-th gate lines GL1 to GLm in response to a gate control signal GCS. In one or more embodiments, the gate control signal GCS may include a start signal for instructing the start of each frame, a horizontal synchronization signal for outputting the gate signals in synchronization with timing at which data signals are applied, and/or the like.

In one or more embodiments, first to m-th light emission control lines EL1 to ELm connected to the sub-pixels SP in the row direction may be further provided. In such embodiments, the gate driver 120 may include a light emission control driver configured to control the first to m-th light emission control lines EL1 to ELm, and the light emission control driver may operate under the control of the controller 150.

The gate driver 120 may be arranged on a (e.g., one) side of the display panel DP. However, the present disclosure is not limited thereto. For example, the gate driver 120 may be divided into two or more drivers that are physically and/or logically separated, and the drivers may be arranged on one side of the display panel DP and on the other side of the display panel DP opposite to the one side. In this way, the gate driver 120 may be arranged on the periphery of the display panel DP in one or more suitable forms according to one or more embodiments.

The data driver 130 may be connected to the sub-pixels SP arranged in a column direction through the first to n-th data lines DL1 to DLn. The data driver 130 may receive image data DATA and a data control signal DCS from the controller 150. The data driver 130 may operate in response to a data control signal DCS. In one or more embodiments, the data control signal DCS may include a source start pulse, a source shift clock, a source output enable signal, and/or the like.

The data driver 130 may apply data signals having grayscale voltages corresponding to the image data DATA to the first to n-th data lines DL1 to DLn by using voltages from the voltage generator 140. When a gate signal is applied to each of the first to m-th gate lines GL1 to GLm, data signals corresponding to the image data DATA may be applied to the data lines DL1 to DLn. Accordingly, the corresponding sub-pixels SP may be to emit light corresponding to the data signals. Accordingly, an image may be displayed on the display panel DP.

In one or more embodiments, the gate driver 120 and the data driver 130 may each include complementary metal-oxide semiconductor (CMOS) circuit elements.

The voltage generator 140 may operate in response to a voltage control signal VCS from the controller 150. The voltage generator 140 may generate a plurality of voltages and provide the generated voltages to components of the display device DD. For example, the voltage generator 140 may generate the plurality of voltages by receiving an input voltage from the outside of the display device DD, adjusting the received voltage, and regulating the adjusted voltage.

The voltage generator 140 may generate a first power supply voltage VDD and a second power supply voltage VSS, and the generated first and second power supply voltages VDD and VSS may be provided to the sub-pixels SP. The first power supply voltage VDD may have a relatively high voltage level, and the second power supply voltage VSS may have a lower voltage level than the first power supply voltage VDD. In one or more embodiments, the first power supply voltage VDD or the second power supply voltage VSS may be provided by an external device of the display device DD.

In one or more embodiments, the voltage generator 140 may generate one or more suitable voltages. For example, the voltage generator 140 may generate an initialization voltage applied to the sub-pixels SP. For example, during a sensing operation for sensing electrical characteristics of transistors and/or light emitting elements of the sub-pixels SP, a set or predetermined reference voltage may be applied to the first to n-th data lines DL1 to DLn, and the voltage generator 140 may generate the reference voltage.

The controller 150 may control all operations (e.g., the overall operation) of the display device DD. The controller 150 may receive input image data IMG from the outside and a control signal CTRL for controlling display of the image data IMG. The controller 150 may provide a gate control signal GCS, a data control signal DCS, and a voltage control signal VCS in response to the control signal CTRL.

The controller 150 may convert the input image data IMG to be suitable for the display device DD or the display panel DP and output the converted image data DATA. In one or more embodiments, the controller 150 may align the input image data IMG to be suitable for the sub-pixels SP of a row unit and output the image data DATA to the sub-pixels SP.

Two or more of the data driver 130, the voltage generator 140, and the controller 150 may be mounted on a single integrated circuit. As illustrated in FIG. 1, the data driver 130, the voltage generator 140, and the controller 150 may be included in a driver integrated circuit DIC. In such embodiments, the data driver 130, the voltage generator 140, and the controller 150 may be functionally separate components in a single driver integrated circuit DIC. However, the present disclosure is not necessarily limited thereto. In one or more embodiments, at least one of the data driver 130, the voltage generator 140, and the controller 150 may be provided as a separate component from the driver integrated circuit DIC.

The display device DD may include at least one temperature sensor 160. The temperature sensor 160 may detect temperature around the temperature sensor 160 and generate temperature data TEP representing the detected temperature. In one or more embodiments, the temperature sensor 160 may be arranged to be adjacent to the display panel DP and/or the driver integrated circuit DIC.

The controller 150 may control one or more suitable operations of the display device DD in response to the temperature data TEP. In one or more embodiments, the controller 150 may control and/or adjust the brightness of an image output from the display panel DP in response to the temperature data TEP. For example, the controller 150 may control components, such as the data driver 130 and/or the voltage generator 140, to control data signals and the first power supply voltage VDD and the second power supply voltage VSS.

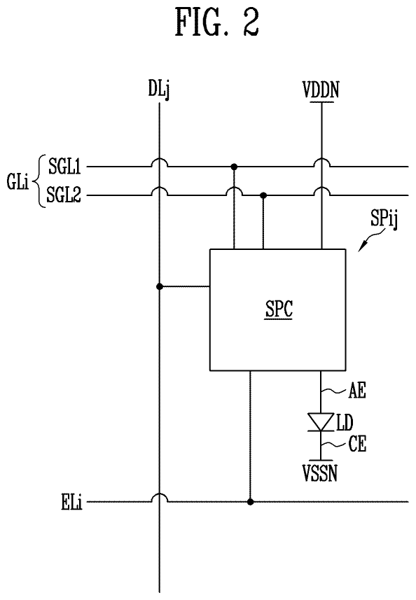

FIG. 2 is a block diagram illustrating one of the sub-pixels of FIG. 1, according to one or more embodiments of the present disclosure.

FIG. 2 illustrates a sub-pixel SPij arranged in the i-th row (i is an integer greater than or equal to 1 and less than or equal to m) and the j-th column (j is an integer greater than or equal to 1 and less than or equal to n) among the sub-pixels SP of FIG. 1.

Referring to FIG. 2, the sub-pixel SPij may include a sub-pixel circuit SPC and a light emitting element LD.

The light emitting element LD may be connected between a first power supply voltage node VDDN and a second power supply voltage node VSSN. In such embodiments, the first power supply voltage node VDDN is a node through which the first power supply voltage VDD of FIG. 1 is transferred, and the second power supply voltage node VSSN is a node through which the second power supply voltage VSS of FIG. 1 is transferred.

An anode electrode AE of the light emitting element LD may be connected to the first power voltage node VDDN through the sub-pixel circuit SPC, and a cathode electrode CE of the light emitting element LD may be connected to the second power voltage node VSSN. For example, the anode electrode AE of the light emitting element LD may be connected to the first power voltage node VDDN through one or more transistors included in the sub-pixel circuit SPC.

The sub-pixel circuit SPC may be connected to the i-th gate line GLi among the first to m-th gate lines GL1 to GLm of FIG. 1, the i-th emission control line ELi among the first to m-th emission control lines EL1 to ELm of FIG. 1, and the j-th data line DLj among the first to n-th data lines DL1 to DLn of FIG. 1. The sub-pixel circuit SPC may control the light emitting element LD in response to signals received through the signal lines.

The sub-pixel circuit SPC may operate in response to a gate signal received through the i-th gate line GLi. The i-th gate line GLi may include one or more sub-gate lines. In one or more embodiments, as illustrated in FIG. 2, the i-th gate line GLi may include first and second sub-gate lines SGL1 and SGL2. The sub-pixel circuit SPC may operate in response to gate signals received through the first sub-gate line SGL1 and the second sub-gate line SGL2. In this way, if (e.g., when) the i-th gate line GLi includes two or more sub-gate lines, the sub-pixel circuit SPC may operate in response to gate signals received through corresponding sub-gate lines.

The sub-pixel circuit SPC may operate in response to an emission control signal received through the i-th emission control line ELi. In one or more embodiments, the i-th emission control line ELi may include one or more sub-emission control lines. If (e.g., when) the i-th emission control line ELi includes two or more sub-emission control lines, the sub-pixel circuit SPC may operate in response to the emission control signals received through the corresponding sub-emission control lines.

The sub-pixel circuit SPC may receive a data signal through the j-th data line DLj. The sub-pixel circuit SPC may store a voltage corresponding to the data signal in response to at least one of the gate signals received through the first sub-gate line SGL1 and the second sub-gate line SGL2. The sub-pixel circuit SPC may control a current flowing from the first power voltage node VDDN to the second power voltage node VSSN through the light emitting element LD according to the stored voltage in response to the emission control signal received through the i-th emission control line ELi. Accordingly, the light emitting element LD may generate and/or emit light with a brightness (luminance) corresponding to the data signal.

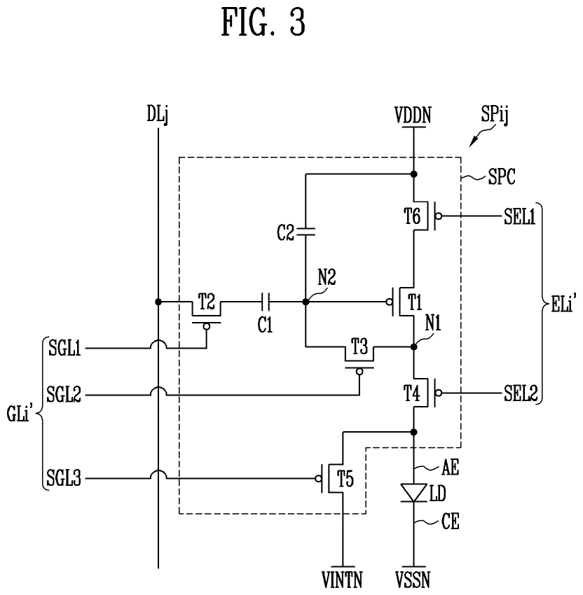

FIG. 3 is a circuit diagram illustrating the sub-pixel of FIG. 2, according to one or more embodiments of the present disclosure.

Referring to FIG. 3, the sub-pixel SPij may include the sub-pixel circuit SPC and the light emitting element LD.

The sub-pixel circuit SPC may be connected to an i-th gate line GLi′, an i-th emission control line ELi′, and a j-th data line DLj. Compared to the i-th gate line GLi of FIG. 2, the i-th gate line GLi′ may further include a third sub-gate line SGL3. Compared to the i-th emission control line ELi of FIG. 2, the i-th emission control line ELi′ may include a first sub-emission control line SEL1 and a second sub-emission control line SEL2.

The sub-pixel circuit SPC may include first to sixth transistors T1 to T6, and first and second capacitors C1 and C2.

The first transistor T1 may be connected between the first power supply voltage node VDDN and a first node N1. A gate of the first transistor T1 may be connected to a second node N2, and accordingly, the first transistor T1 may turn on according to a voltage level of the second node N2. The first transistor T1 may be referred to as a drive transistor.

The second transistor T2 may be connected between the j-th data line DLj and the second node N2. A gate of the second transistor T2 may be connected to the first sub-gate line SGL1, and accordingly, the second transistor T2 may turn on in response to a gate signal of the first sub-gate line SGL1. The second transistor T2 may be referred to as a switching transistor.

The third transistor T3 may be connected between the first node N1 and the second node N2. A gate of the third transistor T3 may be connected to the second sub-gate line SGL2, and accordingly, the third transistor T3) may turn on in response to a gate signal of the second sub-gate line SGL2.

The fourth transistor T4 may be connected between the first node N1 and the anode electrode AE of the light emitting element LD. A gate of the fourth transistor T4 may be connected to the second sub-emission control line SEL2, and accordingly, the fourth transistor T4 may turn on in response to an emission control signal of the second sub-emission control line SEL2.

The fifth transistor T5 may be connected between the anode electrode AE of the light emitting element LD and an initialization voltage node VINTN. The initialization voltage node VINTN may be configured to transmit an initialization voltage. In one or more embodiments, the initialization voltage may be provided by the voltage generator 140 of FIG. 1. In one or more embodiments, the initialization voltage may be provided by a device external to the display device DD. A gate of the fifth transistor T5 may be connected to the third sub-gate line SGL3, and accordingly, the fifth transistor T5 may turn on in response to a gate signal of the third sub-gate line SGL3.

The sixth transistor T6 may be connected between the first power supply voltage node VDDN and the first transistor T1. A gate of the sixth transistor T6 may be connected to the first sub-emission control line SEL1, and accordingly, the sixth transistor T6 may turn on in response to an emission control signal of the first sub-emission control line SEL1.

The first capacitor C1 may be connected between the second transistor T2 and the second node N2. The second capacitor C2 may be connected between the first power supply voltage node VDDN and the second node N2.

In this way, the sub-pixel circuit SPC may include the first to sixth transistors T1 to T6, the first capacitor C1, and the second capacitor C2. However, the present disclosure is not limited thereto. The sub-pixel circuit SPC may be implemented by any one of one or more suitable types (kinds) of circuits including a plurality of transistors and one or more capacitors. For example, the sub-pixel circuit SPC may include two transistors and one capacitor. According to one or more embodiments of the sub-pixel circuit SPC, the number of sub-gate lines included in the i-th gate line GLi′ and the number of sub-emission control lines included in the i-th emission control line ELi′ may be changed.

The first to sixth transistors T1 to T6 may be p-type (kind) transistors. The second capacitor C2 may be connected between the first power supply voltage node VDDN and the second node N2. However, one or more embodiments are not limited thereto. For example, at least one of the first to sixth transistors T1 to T6 may be replaced with N-type (kind) transistors.

In one or more embodiments, the first to sixth transistors T1 to T6 may each include an amorphous silicon semiconductor, a monocrystalline silicon semiconductor, a polycrystalline silicon semiconductor, an oxide semiconductor, and/or the like.

The light emitting element LD may include the anode electrode AE, the cathode electrode CE, and a light emitting layer. The light emitting layer may be arranged between the anode electrode AE and the cathode electrode CE. After the data signal transmitted through the j data line DLj is reflected in a voltage of the second node N2, the fourth and sixth transistors T4 and T6 may turn on if (e.g., when) the emission control signals of the first and second sub-emission control lines SEL1 and SEL2 are enabled to a low voltage level. In one or more embodiments, the first transistor T1 may turn on according to the voltage of the second node N2, and accordingly, a current may flow from the first power voltage node VDDN to the second power voltage node VSSN. The light emitting element LD may be to emit light according to the amount of a flowing current.

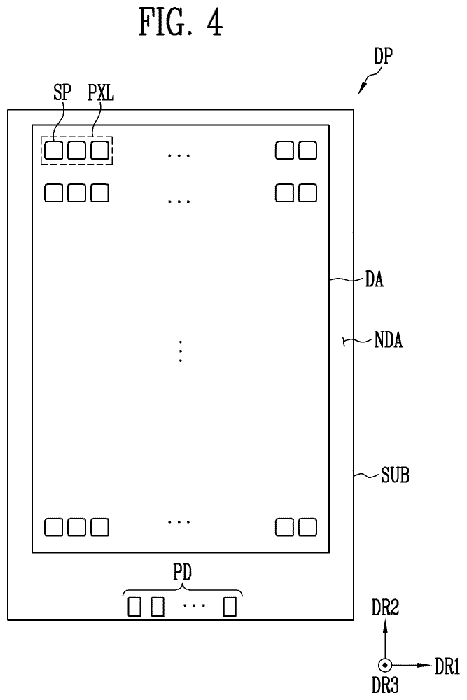

FIG. 4 is a plan view illustrating the display panel DP of FIG. 1, according to one or more embodiments of the present disclosure.

Referring to FIG. 4, one or more embodiments of the display panel DP of FIG. 1 may include a display region DA and a non-display region NDA. The display panel DP may display images through the display region DA. The non-display region NDA may be arranged around the display region DA.

The display panel DP may include a substrate SUB, the sub-pixels SP, and pads PD.

When the display panel DP is used as a display screen for a head mounted display HMD, a virtual reality VR device, a mixed reality MR device, an augmented reality AR device, and/or the like, the display panel DP may be close to a user's eyes. In such embodiments, sub-pixels SP with a relatively high degree of integration may be used. In order to increase the degree of integration of the sub-pixels SP, the substrate SUB may be provided as a silicon substrate. The sub-pixels SP and/or the display panel DP may be formed on the substrate SUB, which is a silicon substrate. the display device DD (see, e.g., FIG. 1) including the display panel DP formed on the substrate SUB, which is a silicon substrate, may be referred to as an organic light emitting diode (OLED) on silicon (OLEDoS) display device.

The sub-pixels SP may be arranged in a display region DA of the substrate SUB. The sub-pixels SP may be arranged in a matrix form in a first direction DR1 and a second direction DR2 intersecting the first direction DR1. However, the present disclosure is not limited thereto. For example, the sub-pixels SP may be arranged in a zigzag form in the first direction DR1 and the second direction DR2. For example, the sub-pixels SP may be arranged in a PENTILE® form (for example, an RGBG matrix or an RGBG structure). PENTILE® is a duly registered trademark of Samsung Display Co. The first direction DR1 may be a row direction, and the second direction DR2 may be a column direction.

Two or more of the plurality of sub-pixels SP may constitute a (e.g., one) pixel PXL. In other words, a pixel PXL may include one or more sub-pixels SP, such as two or more sub-pixels SP.

Components for controlling the sub-pixels SP may be arranged in the non-display region NDA on the substrate SUB. For example, wires (e.g., wiring lines) connected to the sub-pixels SP, such as the first to m-th gate lines GL1 to GLm and the first to n-th data lines DL1 to DLn of FIG. 1, may be arranged in the non-display region NDA.

At least one of the gate driver 120, the data driver 130, the voltage generator 140, the controller 150, and the temperature sensor 160 of FIG. 1 may be integrated in the non-display region NDA of the display panel DP. In one or more embodiments, the gate driver 120 of FIG. 1 may be mounted on the display panel DP but may be arranged in the non-display region NDA. However, the present disclosure is not necessarily limited thereto. In one or more embodiments, the gate driver 120 may be implemented as an integrated circuit separate from the display panel DP. In one or more embodiments, the temperature sensor 160 may be arranged in the non-display region NDA to detect the temperature of the display panel DP.

The pads PD may be arranged in the non-display region NDA of the substrate SUB. The pads PD may be electrically connected to the sub-pixels SP through wires. For example, the pads PD may be connected to the sub-pixels SP through the first to n-th data lines DL1 to DLn.

The pads PD may interface the display panel DP to other components of the display device DD (see, e.g., FIG. 1). In one or more embodiments, voltages and signals for the operation of components included in the display panel DP may be provided from the driver integrated circuit DIC of FIG. 1 through the pads PD. For example, the first to n-th data lines DL1 to DLn may be connected to the driver integrated circuit DIC through the pads PD. For example, the first power supply voltage VDD and the second power supply voltage VSS may be received from the driver integrated circuit DIC through the pads PD. For example, if (e.g., when) the gate driver 120 is mounted on the display panel DP, the gate control signal GCS may be transmitted from the driver integrated circuit DIC to the gate driver 120 through the pads PD.

In one or more embodiments, a circuit board may be electrically connected to the pads PD by using a conductive adhesive material, such as an anisotropic conductive film. In such embodiments, the circuit board may be a flexible circuit board (FPCB) or a flexible film. The driver integrated circuit DIC may be mounted on the circuit board and electrically connected to the pads PD.

In one or more embodiments, the display region DA may have one or more suitable shapes. The display region DA may have the shape of a closed loop including straight and/or curved edges. For example, the display region DA may have shapes, such as a polygon, a circle, a semicircle, and/or an ellipse.

In one or more embodiments, the display panel DP may have a flat display surface. However, the present disclosure is not necessarily limited thereto. In one or more embodiments, the display panel DP may have a display surface which is at least partially rounded. In one or more embodiments, the display panel DP may be bendable, foldable, or rollable. In such embodiments, the display panel DP and/or the substrate SUB may include flexible materials.

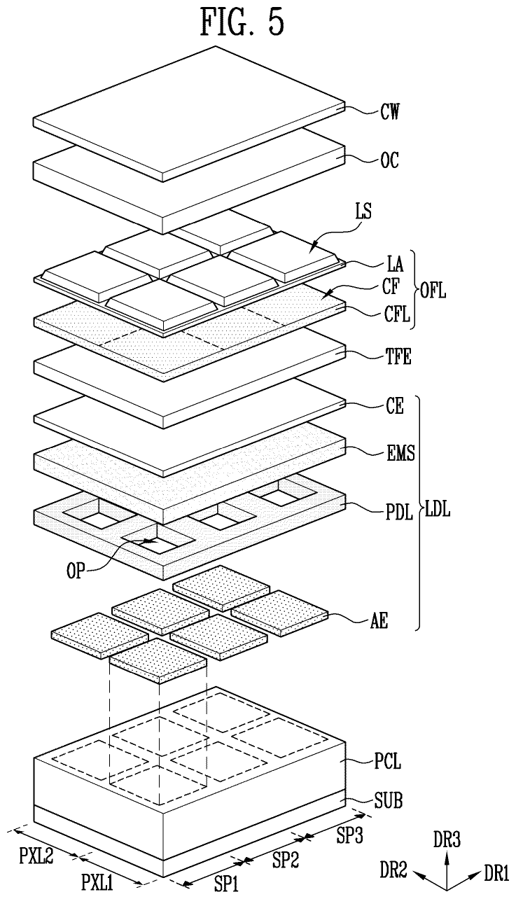

FIG. 5 is an exploded perspective view illustrating a part of the display panel of FIG. 4, according to one or more embodiments of the present disclosure.

In FIG. 5, a part of the display panel DP corresponding to two pixels PXL1 and PXL2 among the pixels PXL of FIG. 4 is schematically illustrated for the sake of clear and concise description. The part of the display panel DP corresponding to the remaining pixels may be configured similarly.

Referring to FIGS. 4 and 5, each of the first and second pixels PXL1 and PXL2 may include first, second, and third sub-pixels SP1, SP2, and SP3. However, the present disclosure is not limited thereto. For example, each of the first and second pixels PXL1 and PXL2 may include four sub-pixels or two sub-pixels.

FIG. 5 illustrates that the first, second, and third sub-pixels SP1, SP2, and SP3 may each have a rectangular shape and have the same size when viewed in a third direction DR3 intersecting the first direction DR1 and the second direction DR2. However, the present disclosure is not limited thereto. The first, second, and third sub-pixels SP1, SP2, and SP3 may be modified to have one or more suitable shapes.

The display panel DP may include the substrate SUB, a pixel circuit layer PCL, a light emitting element layer LDL, an encapsulation layer TFE, an optical function layer OFL, an overcoat layer OC, and a cover window CW.

In one or more embodiments, the substrate SUB may include a silicon wafer substrate formed through a semiconductor process. The substrate SUB may include a semiconductor material suitable for forming circuit elements. For example, the semiconductor material may include silicon (Si), germanium (Ge), and/or silicon-germanium (SiGe). The substrate SUB may also be provided from a bulk wafer, an epitaxial layer, a silicon on insulator (SOI) layer, or a semiconductor on insulator (SeOI) layer. In one or more embodiments, the substrate SUB may include a glass substrate. In one or more embodiments, the substrate SUB may include a polyimide (PI) substrate.

The pixel circuit layer PCL may be arranged on the substrate SUB. The substrate SUB and/or the pixel circuit layer PCL may include insulating layers and conductive patterns between the insulating layers. The conductive patterns of the pixel circuit layer PCL may function as at least a part of circuit elements, wires, and/or the like. The conductive patterns may include copper, but the present disclosure is not limited thereto.

The circuit elements may include a sub-pixel circuit SPC (see, e.g., FIG. 2) for each of the first, second, and third sub-pixels SP1, SP2, and SP3. The sub-pixel circuit SPC may include transistors and one or more capacitors. The transistor may each include a semiconductor portion including a source region, a drain region, and a channel region, and a gate electrode overlapping the semiconductor portion. In one or more embodiments, if (e.g., when) the substrate SUB is provided as a silicon substrate, the semiconductor portion may be included in the substrate SUB, and the gate electrode may be included in the pixel circuit layer PCL as a conductive pattern of the pixel circuit layer PCL. In one or more embodiments, if (e.g., when) the substrate SUB is provided as a glass substrate or a PI substrate, the semiconductor portion and the gate electrode may be included in the pixel circuit layer PCL. Each capacitor may include electrodes separated from each other. For example, each capacitor may include electrodes spaced and/or apart (e.g., spaced apart or separated) from each other on a plane (e.g., in a plan view) defined by the first direction DR1 and the second direction DR2. For example, each capacitor may include electrodes spaced and/or apart (e.g., spaced apart or separated) from each other in the third direction DR3 with an insulating layer therebetween.

Wires of the pixel circuit layer PCL may include signal lines, such as a gate line, an emission control line, and a data line, connected to each of the first, second, and third sub-pixels SP1, SP2, and SP3. The wires may further include a wire connected to the first power voltage node VDDN of FIG. 2. In one or more embodiments, the wires may further include a wire connected to the second power voltage node VSSN of FIG. 2.

The light emitting element layer LDL may include anode electrodes AE, a pixel definition layer PDL, a light emitting structure EMS, and a cathode electrode CE.

The anode electrodes AE may be arranged on the pixel circuit layer PCL. The anode electrodes AE may be in contact with circuit elements of the pixel circuit layer PCL. The anode electrodes AE may each include an opaque conductive material capable of reflecting light, but the present disclosure is not limited thereto.

The pixel definition layer PDL may be arranged on the anode electrodes AE. The pixel definition layer PDL may include openings OP exposing a part of each of the anode electrodes AE. Light emitting regions corresponding to the first to third sub-pixels SP1 to SP3 may be defined by the openings OP of the pixel definition layer PDL. In one or more embodiments, it may be understood that the light emitting regions corresponding to the first to third sub-pixels SP1 to SP3 are defined by the anode electrodes AE. In a region adjacent to a boundary of neighboring sub-pixels, the pixel definition layer PDL may include separators that cause discontinuity in the light emitting structure EMS. In such embodiments, it may be understood that light emitting regions corresponding to the first to third sub-pixels SP1 to SP3 are defined by the separators of the pixel definition layer PDL.

In one or more embodiments, the pixel definition layer PDL may include an inorganic material. In such embodiments, the pixel definition layer PDL may include a plurality of stacked inorganic layers. For example, the pixel definition layer PDL may include silicon oxide (SiOₓ, where 0<x≤2, e.g., SiO₂) and silicon nitride (SiₓN_{y}, where 0<x≤3 and 0<y≤4, e.g., Si₃N₄). In one or more embodiments, the pixel definition layer PDL may include an organic material. However, the material of the pixel definition layer PDL is not limited thereto.

The light emitting structure EMS may be arranged on the anode electrodes AE exposed by the openings OP of the pixel definition layer PDL. The light emitting structure EMS may include a light emitting layer configured to generate and/or emit light, an electron transfer layer configured to transfer electrons, a hole transfer layer configured to transport holes, and/or the like.

In one or more embodiments, the light emitting structure EMS may be arranged entirely on the pixel definition layer PDL while filling the openings OP of the pixel definition layer PDL. For example, the light emitting structure EMS may extend over the first to third sub-pixels SP1 to SP3. In such embodiments, at least some of the layers in the light emitting structure EMS may be disconnected or bent at boundaries between the first to third sub-pixels SP1 to SP3. However, the present disclosure is not limited thereto. For example, portions of the light emitting structure EMS corresponding to the first to third sub-pixels SP1 to SP3 may be separated from each other, and each of the portions may be arranged in the openings OP of the pixel definition layer PDL.

The cathode electrode CE may be arranged on the light emitting structure EMS. The cathode electrode CE may extend across the first to third sub-pixels SP1 to SP3. In this way, the cathode electrode CE may be provided as a common electrode for the first to third sub-pixels SP1 to SP3.

The cathode electrode CE may be a thin metal layer having a thickness that is sufficient to transmit light, which is emitted from the light emitting structure EMS, therethrough. The cathode electrode CE may be formed of a metal material or a transparent conductive material to have a relatively thin thickness. In one or more embodiments, the cathode electrode CE may include at least one of one or more suitable transparent conductive materials, such as indium tin oxide, indium zinc oxide, indium tin zinc oxide, aluminum zinc oxide, gallium zinc oxide, zinc tin oxide, and/or gallium tin oxide. In one or more embodiments, the cathode electrode CE may include at least one of silver (Ag), magnesium (Mg), and/or a (e.g., any suitable) mixture thereof. However, the material of the cathode electrode CE is not limited thereto.

It may be understood that any one of the anode electrodes AE, a portion of the light emitting structure EMS overlapping therewith, and a portion of the cathode electrode CE overlapping therewith, may constitute one light emitting element LD (see, e.g., FIG. 2). For example, each of the light emitting elements of the first to third sub-pixels SP1 to SP3 may include one anode electrode, a portion of the light emitting structure EMS overlapping the one anode electrode, and a portion of a cathode electrode CE overlapping the portion of the light emitting structure EMS. In each of the first to third sub-pixels SP1 to SP3, holes injected from the anode electrodes AE and electrons injected from the cathode electrode CE are transferred into a light emitting layer of the light emitting structure EMS to form excitons, and if (e.g., when) the excitons are shifted from an excited state to a ground state, light may be generated and/or emitted. The brightness of light may be determined according to the amount of a current flowing through a light emitting layer. A wavelength range of the generated light may be determined according to a configuration of the light emitting layer.

The encapsulation layer TFE may be arranged on the cathode electrode CE. The encapsulation layer TFE may cover the light emitting element layer LDL and/or the pixel circuit layer PCL. The encapsulation layer TFE may be configured to prevent or reduce the likelihood of oxygen and/or moisture penetrating into the light emitting element layer LDL. In one or more embodiments, the encapsulation layer TFE may include a structure in which one or more inorganic films and one or more organic films are alternately stacked. For example, the inorganic film may include silicon nitride, silicon oxide, or silicon oxynitride (SiOₓN_{y,} e.g., the range for x may be from 0 to 2, and the range for y may be from 0 to 4). For example, the organic film may include an organic insulating material, such as an acrylic resin, an epoxy resin, a phenol resin, a polyamide resin, a polyimide resin, an unsaturated polyester resin, a polyphenylene ether resin, a polyphenylene sulfide resin, or benzocyclobutene (BCB). However, the materials of the organic film and the inorganic film of the encapsulation layer TFE are not limited thereto.

In order to improve an encapsulation efficiency of the encapsulation layer TFE, the encapsulation layer TFE may further include a thin film including aluminum oxide (AlₓO_{y}, e.g., the range for x may be from 0 to 2, and the range for y may be from 0 to 3, e.g., Al₂O₃). The thin film including aluminum oxide may be placed on an upper surface of the encapsulation layer TFE facing (e.g., opposite to) the optical function layer OFL and/or on a lower surface of the encapsulation layer TFE facing (e.g., opposite to) the light emitting device layer LDL.

The thin film including aluminum oxide may be formed by using an atomic layer deposition (ALD) method. However, the present disclosure is not limited thereto. The encapsulation layer TFE may further include a thin film formed of at least one of one or more suitable materials for increasing the encapsulation efficiency.

The optical function layer OFL may be arranged on the encapsulation layer TFE. The optical function layer OFL may include a color filter layer CFL and a lens array LA.

The color filter layer CFL may be arranged between the encapsulation layer TFE and the lens array LA. The color filter layer CFL may filter the light emitted from the light emitting structure EMS to selectively output light in a wavelength range or of a color corresponding to each sub-pixel. The color filter layer CFL may include color filters CF respectively corresponding to the first to third sub-pixels SP1 to SP3, and each of the color filters CF may be to transmit therethrough light in a wavelength range corresponding to a corresponding sub-pixel. For example, a color filter corresponding to the first sub-pixel SP1 may be to transmit red color light therethrough, a color filter corresponding to the second sub-pixel SP2 may be to transmit green color light therethrough, and a color filter corresponding to the third sub-pixel SP3 may be to transmit blue color light therethrough. At least some of the color filters CF may not be provided depending on the light emitted from the light emitting structure EMS of each sub-pixel.

The lens array LA may be arranged on the color filter layer CFL. The lens array LA may include lenses LS respectively corresponding to the first to third sub-pixels SP1 to SP3. Each of the lenses LS may increase light emission efficiency by outputting the light emitted from the light emitting structure EMS to an intended path. The lens array LA may have a relatively high refractive index. For example, the lens array LA may have a higher refractive index than the overcoat layer OC. In one or more embodiments, the lenses LS may each include an organic material. In one or more embodiments, the lenses LS may each include an acrylic material. However, the materials of the lenses LS are not limited thereto.

In one or more embodiments, at least some of the color filters CF of the color filter layer CFL and at least some of the lenses LS of the lens array LA may be shifted in a direction parallel to a plane defined by the first and second directions DR1 and DR2, with respect to the openings OP of the pixel definition layer PDL. For example, in a central region of the display region DA, the center of the color filter and the center of the lens may be aligned or may overlap with the center of the opening OP of the corresponding pixel definition layer PDL when viewed in the third direction DR3. For example, in the central region of the display region DA, the opening OP of the pixel definition layer PDL may completely overlap a corresponding color filter of the color filter layer CFL and a corresponding lens of the lens array LA. In a region adjacent to the non-display region NDA of the display region DA, the center of the color filter and the center of the lens may be shifted in a plane direction from the center of the opening OP of the corresponding pixel definition layer PDL when viewed in the third direction DR3. For example, in the region adjacent to the non-display region NDA of the display region DA, the opening OP of the pixel definition layer PDL may partially overlap a corresponding color filter of the color filter layer CFL and a corresponding lens of the lens array LA. Accordingly, in the center of the display region DA, the light emitted from the light emitting structure EMS may be efficiently output in a normal (e.g., perpendicular) direction of a display surface. In the periphery of the display region DA, the light emitted from the light emitting structure EMS may be efficiently output in a direction inclined by a set or predetermined angle with respect to the normal (e.g., perpendicular) direction of the display surface.

The overcoat layer OC may be arranged on the lens array LA. The overcoat layer OC may cover the optical function layer OFL, the encapsulation layer TFE, the light emitting structure EMS, and/or the pixel circuit layer PCL. The overcoat layer OC may include one or more materials suitable for protecting layers under the overcoat layer OC from foreign substances such as dust, moisture, and/or the like. For example, the overcoat layer OC may include at least one of an inorganic insulating film and/or an organic insulating film. For example, the overcoat layer OC may include epoxy, but the present disclosure is not limited thereto. The overcoat layer OC may have a lower refractive index than the lens array LA.

The cover window CW may be arranged on the overcoat layer OC. The cover window CW may be configured to protect layers under the cover window CW. The cover window CW may have a higher refractive index than the overcoat layer OC. The cover window CW may include glass, but the present disclosure is not limited thereto. For example, the cover window CW may be an encapsulation glass configured to protect components arranged thereunder. In one or more embodiments, the cover window CW may not be provided.

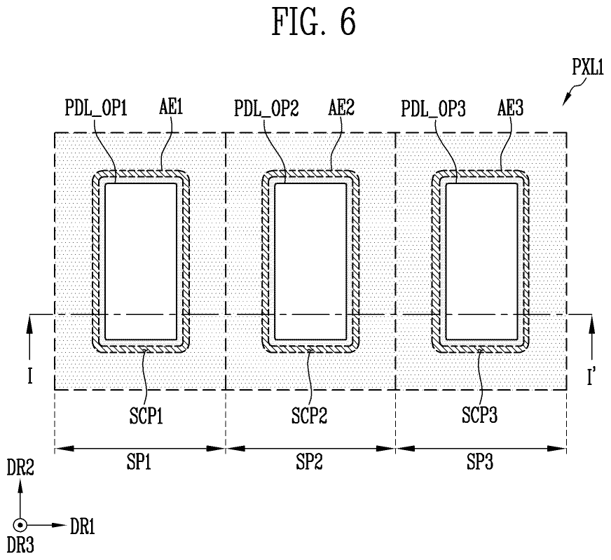

FIG. 6 is a plan view illustrating one of the pixels of FIG. 5, according to one or more embodiments of the present disclosure. In FIG. 6, the first pixel PXL1 among the first and second pixels PXL1 and PXL2 of FIG. 5 is schematically illustrated for the sake of clear and concise description. The other pixels may be configured similarly to the first pixel PXL1.

Referring to FIGS. 5 and 6, the first pixel PXL1 may include the first to third sub-pixels SP1 to SP3 arranged in the first direction DR1.

The first sub-pixel SP1 may include a first anode electrode AE1, a first sacrificial pattern SCP1, and a pixel definition layer PDL around (e.g., surrounding) the first anode electrode AE1.

The pixel definition layer PDL may be formed to be around (e.g., surround) the first anode electrode AE1. The pixel definition layer PDL may include a first opening PDL_OP1 corresponding to a part of the first anode electrode AE1 exposed by the pixel definition layer PDL. According to one or more embodiments, the first opening PDL_OP1 of the pixel definition layer PDL may define a light emitting region of the first sub-pixel SP1. The first opening PDL_OP1 of the pixel definition layer PDL may be a region where light is emitted from a portion of the light emitting structure EMS corresponding to the first sub-pixel SP1.

The pixel definition layer PDL may partially overlap an edge (e.g., outer edge) of the first anode electrode AE1. In one or more embodiments, the first sacrificial pattern SCP1 may be arranged in a part of a region where the first anode electrode AE1 and the pixel definition layer PDL overlap each other on a plane (e.g., in a plan view). The first sacrificial pattern SCP1 may be arranged along an edge (e.g., outer edge) of the first anode electrode AE1 to be around (e.g., surround) the first opening PDL_OP1 of the pixel definition layer PDL.

The second sub-pixel SP2 may include a second anode electrode AE2, a second sacrificial pattern SCP2, and the pixel definition layer PDL around the second anode electrode AE2.

The pixel definition layer PDL may be formed to be around (e.g., surround) the second anode electrode AE2. The pixel definition layer PDL may include a second opening PDL_OP2 corresponding to a part of the second anode electrode AE2 exposed by the pixel definition layer PDL. According to one or more embodiments, the second opening PDL_OP2 of the pixel definition layer PDL may define a light emitting region of the second sub-pixel SP2. The second opening PDL_OP2 of the pixel definition layer PDL may be a region where light is emitted from a portion of the light emitting structure EMS corresponding to the second sub-pixel SP2.

The pixel definition layer PDL may partially overlap an edge (e.g., outer edge) of the second anode electrode AE2. In one or more embodiments, the second sacrificial pattern SCP2 may be arranged in a part of a region where the second anode electrode AE2 and the pixel definition layer PDL overlap each other on a plane (e.g., in a plan view). The second sacrificial pattern SCP2 may be arranged along an edge (e.g., outer edge) of the second anode electrode AE2 to be around (e.g., surround) the second opening PDL_OP2 of the pixel definition layer PDL.

The third sub-pixel SP3 may include a third anode electrode AE3, a third sacrificial pattern SCP3, and the pixel definition layer PDL around the third anode electrode AE3.

The pixel definition layer PDL may be around (e.g., surround) the third anode electrode AE3. The pixel definition layer PDL may include a third opening PDL_OP3 corresponding to a part of the third anode electrode AE3 exposed by the pixel definition layer PDL. According to one or more embodiments, the third opening PDL_OP3 of the pixel definition layer PDL may define a light emitting region of the third sub-pixel SP3. The third opening PDL_OP3 of the pixel definition layer PDL may be a region where light is emitted from a portion of the light emitting structure EMS corresponding to the third sub-pixel SP3.

The pixel definition layer PDL may partially overlap an edge (e.g., outer edge) of the third anode electrode AE3. In one or more embodiments, the third sacrificial pattern SCP3 may be arranged in a part of a region where the third anode electrode AE3 and the pixel definition layer PDL overlap each other on a plane (e.g., in a plan view). The third sacrificial pattern SCP3 may be arranged along an edge (e.g., outer edge) of the third anode electrode AE3 to be around (e.g., surround) the third opening PDL_OP3 of the pixel definition layer PDL.

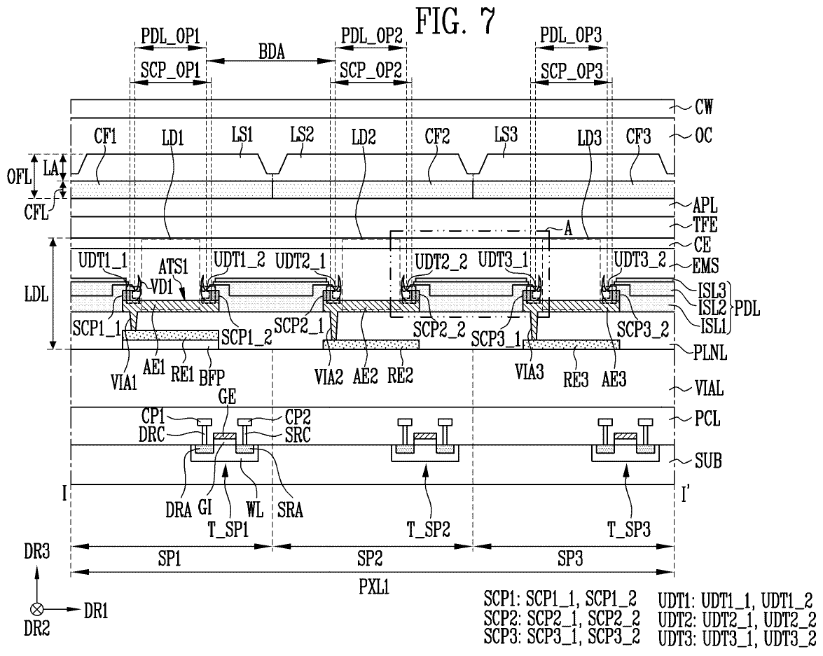

FIG. 7 is a cross-sectional view taken along the line I-I′ of FIG. 6, according to one or more embodiments of the present disclosure.

Referring to FIG. 7, the substrate SUB and the pixel circuit layer PCL arranged on the substrate SUB may be provided.

The substrate SUB may include a silicon wafer substrate formed through a semiconductor process. For example, the substrate SUB may include silicon, germanium, and/or silicon-germanium.

The pixel circuit layer PCL may be arranged on the substrate SUB. The substrate SUB and the pixel circuit layer PCL may include respective circuit elements of the first to third sub-pixels SP1 to SP3. For example, the substrate SUB and the pixel circuit layer PCL may include a transistor T_SP1 of the first sub-pixel SP1, a transistor T_SP2 of the second sub-pixel SP2, and a transistor T_SP3 of the third sub-pixel SP3. The transistor T_SP1 of the first sub-pixel SP1 may be one of transistors included in the sub-pixel circuit SPC (see, e.g., FIG. 2) of the first sub-pixel SP1, the transistor T_SP2 of the second sub-pixel SP2 may be one of transistors included in the sub-pixel circuit SPC of the second sub-pixel SP2, and the transistor T_SP3 of the third sub-pixel SP3 may be one of the transistors included in the sub-pixel circuit SPC of the third sub-pixel SP3. For the sake of clear and concise description, FIG. 7 illustrates one of the transistors of each sub-pixel, and the other circuit elements may not be provided.

The transistor T_SP1 of the first sub-pixel SP1 may include a source region SRA, a drain region DRA, and a gate electrode GE.

The source region SRA and the drain region DRA may be arranged in the substrate SUB. A well WL formed through an ion implantation process is arranged in the substrate SUB, and the source region SRA and the drain region DRA may be separated from each other in the well WL. A region between the source region SRA and the drain region DRA in the well WL may be defined as a channel region. The gate electrode GE overlaps a channel region between the source region SRA and the drain region DRA and may be arranged in the pixel circuit layer PCL. The gate electrode GE may be separated from the well WL or the channel region by an insulating material, such as a gate insulating layer GI. The gate electrode GE may include a conductive material.

A plurality of layers included in the pixel circuit layer PCL may include conductive patterns arranged between insulating layers, and the conductive patterns may include a first conductive pattern CP1 and a second conductive pattern CP2. The first conductive pattern CP1 may be electrically connected to the drain region DRA through a drain connection portion DRC passing through one or more insulating layers. The second conductive pattern CP2 may be electrically connected to the source region SRA through a source connection portion SRC passing through one or more insulating layers.

As the gate electrode GE, the first conductive pattern CP1, and the second conductive pattern CP2 are connected to other circuit elements and/or wires, the transistor T_SP1 of the first sub-pixel SP1 may be provided as one of the transistors of the first sub-pixel SP1.

The transistor T_SP2 of the second sub-pixel SP2 and the transistor T_SP3 of the third sub-pixel SP3 may be similar to the transistor T_SP1 of the first sub-pixel SP1.

In this way, the substrate SUB and the pixel circuit layer PCL may include circuit elements of the first to third sub-pixels SP1 to SP3.

A via layer VIAL may be arranged on the pixel circuit layer PCL. The via layer VIAL may cover the pixel circuit layer PCL and may have an entirely flat surface. The via layer VIAL may be configured to flatten step differences on the pixel circuit layer PCL. The via layer VIAL may include at least one of silicon oxide (SiOₓ), silicon nitride (SiₓN_{y}), and silicon carbon nitride (SiCN), but the present disclosure is not limited thereto.

A light emitting element layer LDL may be arranged on the via layer VIAL. The light emitting element layer LDL may include first to third reflective electrodes RE1 to RE3, a planarization layer PLNL, first to third anode electrodes AE1 to AE3, a pixel definition layer PDL, a light emitting structure EMS, and a cathode electrode CE.

On the via layer VIAL, the first to third reflective electrodes RE1 to RE3 may be respectively arranged on the first to third sub-pixels SP1 to SP3. Each of the first to third reflective electrodes RE1 to RE3 may be in contact with a circuit element arranged on the pixel circuit layer PCL through a via passing through the via layer VIAL.

The first to third reflective electrodes RE1 to RE3 may function as full mirrors that reflect the light emitted from the light emitting structure EMS toward a display surface (or a cover window CW). The first to third reflective electrodes RE1 to RE3 may include metal materials suitable for reflecting light. The first to third reflective electrodes RE1 to RE3 may each include at least one of aluminum (Al), silver (Ag), magnesium (Mg), platinum (Pt), palladium (Pd), gold (Au), nickel (Ni), neodymium (Nd), iridium (Ir), chromium (Cr), titanium (Ti), and/or an alloy of two or more materials selected therefrom, but the present disclosure is not limited thereto.

In one or more embodiments, connection electrodes may be respectively arranged under the first to third reflective electrodes RE1 to RE3. The connection electrodes may improve electrical connection characteristics between the corresponding reflective electrode and circuit elements of the pixel circuit layer PCL. The connection electrodes may each have a multilayer structure. The multilayer structure may include titanium (Ti), titanium nitride (TiN), tantalum nitride (TaN), and/or the like, but the present disclosure is not limited thereto. In one or more embodiments, the corresponding reflective electrode may be provided between the multilayers of the connection electrode.

A buffer pattern BFP may be arranged under at least one of the first to third reflective electrodes RE1 to RE3. The buffer pattern BFP may include an inorganic material, such as silicon carbon nitride, but the present disclosure is not limited thereto. By disposing/arranging the buffer pattern BFP, a height of a corresponding reflective electrode in the third direction DR3 may be adjusted. For example, the buffer pattern BFP may be arranged between the first reflective electrode RE1 and the via layer VIAL to adjust a height of the first reflective electrode RE1.

The first to third reflective electrodes RE1 to RE3 may function as full mirrors, and the cathode electrode CE may function as a half mirror. For example, the first to third reflective electrodes RE1 to RE3 and the cathode electrode CE may provide a resonance structure in a corresponding sub-pixel. The light emitted from a light emitting layer of the light emitting structure EMS may be amplified by reciprocating between a corresponding reflective electrode and the cathode electrode CE, and the amplified light may be output through the cathode electrode CE. In this way, a distance between each reflective electrode and the cathode electrode CE may be understood as a resonance distance for the light emitted from the light emitting layer of the corresponding light emitting structure EMS.

The first sub-pixel SP1 may have a shorter resonance distance than other sub-pixels by the buffer pattern BFP. The resonance distance adjusted in this way may cause the light in a specific wavelength range (for example, a red color) to be effectively and efficiently amplified. Accordingly, the first sub-pixel SP1 may effectively and efficiently output the light in a corresponding wavelength range.

Although FIG. 7 illustrates that the buffer pattern BFP is provided to the first sub-pixel SP1 and is not provided to the second and third sub-pixels SP2 and SP3, the present disclosure is not limited thereto. The buffer pattern BFP may also be provided to at least one of the second and/or third sub-pixels SP2 and SP3 to adjust a resonance distance of at least one of the second and/or third sub-pixels SP2 and SP3. For example, the first to third sub-pixels SP1 to SP3 may respectively correspond to red, green, and blue, a distance between the first reflective electrode RE1 and the cathode electrode CE may be shorter than a distance between the second reflective electrode RE2 and the cathode electrode CE, and a distance between the second reflective electrode RE2 and the cathode electrode CE may be shorter than a distance between the third reflective electrode RE3 and the cathode electrode CE.

In order to planarize a step difference between the first to third reflective electrodes RE1 to RE3, a planarization layer PLNL may be arranged on the via layer VIAL and the first to third reflective electrodes RE1 to RE3. The planarization layer PLNL may cover the first to third reflective electrodes RE1 to RE3 and the via layer VIAL as a whole and may have a planar surface. In one or more embodiments, the planarization layer PLNL may not be provided.

On the planarization layer PLNL, first to third anode electrodes AE1 to AE3 may be arranged to respectively overlap the first to third reflective electrodes RE1 to RE3. The first to third anode electrodes AE1 to AE3 may be respectively connected to the first to third reflective electrodes RE1 to RE3. The first anode electrode AE1 may be connected to the first reflective electrode RE1 through a first via VIA1 passing through the planarization layer PLNL. The second anode electrode AE2 may be connected to the second reflective electrode RE2 through a second via VIA2 penetrating (e.g., passing through) the planarization layer PLNL. The third anode electrode AE3 may be connected to the third reflective electrode RE3 through a third via VIA3 penetrating the planarization layer PLNL.

In one or more embodiments, the first to third anode electrodes AE1 to AE3 may each include at least one transparent conductive material, such as indium tin oxide (ITO), indium zinc oxide (IZO), zinc oxide (ZnOₓ, where 0<x≤1), indium gallium zinc oxide (IGZO), and/or indium tin zinc oxide (ITZO). However, the materials of the first to third anode electrodes AE1 to AE3 are not limited thereto. For example, the first to third anode electrodes AE1 to AE3 may each be arranged as a multilayer including titanium (Ti), aluminum (Al), and/or titanium nitride (TiN).

Sacrificial patterns SCP1 to SCP3 may be respectively and partially arranged on the first to third anode electrodes AE1 to AE3. The sacrificial patterns SCP1 to SCP3 may respectively have sacrificial openings SCP_OP1 to SCP_OP3 partially exposing the first to third anode electrodes AE1 to AE3.

The sacrificial patterns SCP1 to SCP3 may each include a metal material. The sacrificial patterns SCP1 to SCP3 may each include one of aluminum (Al), silver (Ag), magnesium (Mg), platinum (Pt), palladium (Pd), gold (Au), nickel (Ni), neodymium (Nd), iridium (Ir), chromium (Cr), and/or titanium (Ti), but the present disclosure is not limited thereto.

In other words, sacrificial patterns SCP1 to SCP3 may be partially arranged on the first to third anode electrodes AE1 to AE3, with sacrificial openings SCP_OP1 to SCP_OP3 that partially expose these electrodes. These sacrificial patterns may include a metal material such as aluminum (Al), silver (Ag), magnesium (Mg), platinum (Pt), palladium (Pd), gold (Au), nickel (Ni), neodymium (Nd), iridium (Ir), chromium (Cr), and/or titanium (Ti).

A pixel definition layer PDL may be partially arranged on the first to third anode electrodes AE1 to AE3 and may be arranged on the planarization layer PLNL. The pixel definition layer PDL may have openings PDL_OP1 to PDL_OP3 partially exposing the first to third anode electrodes AE1 to AE3. A region overlapping the pixel definition layer PDL may be understood as a boundary region BDA between neighboring sub-pixels.

In one or more embodiments, the openings PDL_OP1 to PDL_OP3 of the pixel definition layer PDL may respectively overlap the sacrificial openings SCP_OP1 to SCP_OP3 of the sacrificial patterns SCP1 to SCP3. Upper surface ATS1 of the first to third anode electrodes AE1 to AE3 may be separated from the pixel definition layer PDL respectively with sacrificial patterns SCP1 to SCP3 therebetween. Due to the sacrificial patterns SCP1 to SCP3, the first to third anode electrodes AE1 to AE3 may be prevented from being damaged (or the likelihood of damage may be reduced) in a process of forming the openings PDL_OP1 to PDL_OP3 of the pixel definition layer PDL.

The pixel definition layer PDL may protrude, in a cross-section, from the sacrificial patterns SCP1 to SCP3 in the first direction DR1 or in a direction opposite to the first direction DR1. In this way, widths of the sacrificial openings SCP_OP1 to SCP_OP3 of the sacrificial patterns SCP1 to SCP3 may be greater than widths of the openings PDL_OP1 to PDL_OP3 of the pixel definition layer PDL. For example, during a manufacturing process, the pixel definition layer PDL may be undercut to include portions that do not overlap the first to third anode electrodes AE1 to AE3 and the sacrificial patterns SCP1 to SCP3. For example, a protruding portion of the pixel definition layer PDL and side surfaces of the sacrificial patterns SCP1 to SCP3 may have first to third undercut shapes UDT1 to UDT3. For example, the pixel definition layer PDL may include shapes of eaves on the sacrificial patterns SCP1 to SCP3 (e.g., the pixel definition layer PDL may have portions that overhang the sacrificial patterns SCP1 to SCP3 similar to the shape of eaves).

The first undercut shape UDT1 may be provided, on the first anode electrode AE1, by the first sacrificial pattern SCP1 and a part of the pixel definition layer PDL protruding more than (e.g., protruding farther towards a center of the first sub-pixel SP1 relative to or extending beyond) the first sacrificial pattern SCP1. The second undercut shape UDT2 may be provided, on the second anode electrode AE2, by the second sacrificial pattern SCP2 and a part of the pixel definition layer PDL protruding more than (e.g., protruding farther towards a center of the second sub-pixel SP2 relative to or extending beyond) the second sacrificial pattern SCP2. The third undercut shape UDT3 may be provided, on the third anode electrode AE3, by the third sacrificial pattern SCP3 and a part of the pixel definition layer PDL protruding more than (e.g., protruding farther towards a center of the third sub-pixel SP3 relative to or extending beyond) the third sacrificial pattern SCP3.

In other words, the pixel definition layer PDL is partially arranged on the first to third anode electrodes AE1 to AE3 and the planarization layer PLNL, with openings PDL_OP1 to PDL_OP3 that partially expose these electrodes. The sacrificial patterns SCP1 to SCP3, made of metal materials, are also partially arranged on these anode electrodes and have openings SCP_OP1 to SCP_OP3 that overlap with those of the pixel definition layer PDL. This arrangement helps prevent damage to the anode electrodes during the formation of the pixel definition layer PDL openings. The pixel definition layer PDL may protrude from the sacrificial patterns, creating undercut shapes UDT1 to UDT3 that resemble eaves, which further protect the anode electrodes by ensuring the pixel definition layer PDL does not overlap them directly.

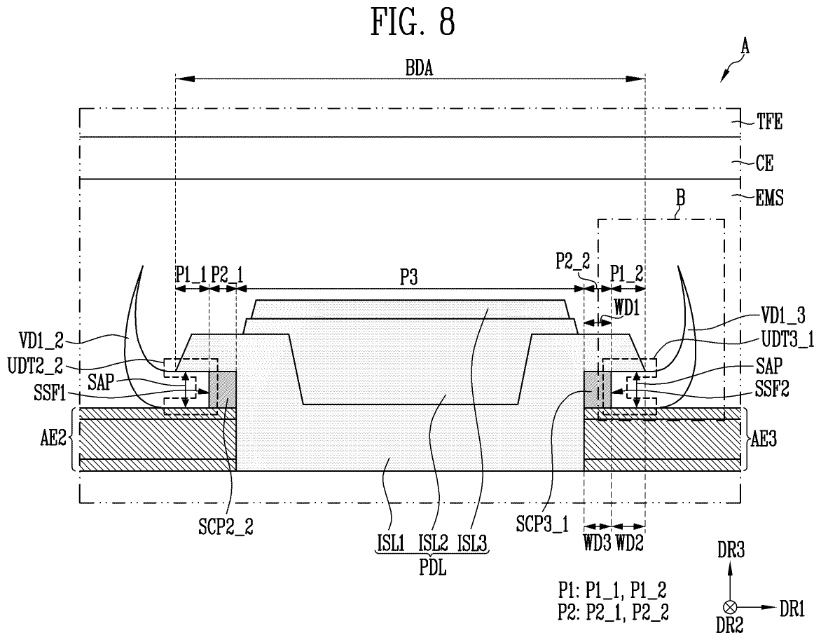

In one or more embodiments, the pixel definition layer PDL may include a plurality of inorganic insulating layers. Each of the plurality of inorganic insulating layers may include at least one of silicon oxide (SiOₓ) and silicon nitride (SiₓN_{y}). For example, the pixel definition layer PDL may include a first insulating layer ISL1, a second insulating layer ISL2, and a third inorganic insulating layer ISL3 that are sequentially stacked. The first insulating layer ISL1 may include first to third portions P1 to P3 (see, e.g, FIG. 8). The second and third insulating layers ISL2 and ISL3 may be arranged on the first insulating layer ISL1. The first to third insulating layers ISL1 to ISL3 may be inorganic insulating layers and may each include at least one of silicon oxide (SiOₓ) and silicon nitride (SiₓN_{y}), but the present disclosure is not limited thereto. The first to third inorganic insulating layers ISL1 to ISL3 may each have a step-shaped cross-section in each of the regions adjacent to the openings PDL_OP1 to PDL_OP3 of the pixel definition layer PDL.

The undercut shapes UDT1 to UDT3 may cause discontinuity in the light emitting structure EMS adjacent to the boundary region BDA. For example, the light emitting structure EMS may be partially disconnected. For example, due to the undercut shapes UDT1 to UDT3, the light emitting structure EMS may be disconnected or bent in a region adjacent to the boundary region BDA.

Due to the undercut shapes UDT1 to UDT3, discontinuity, such as a first void VD1, may be made in a region adjacent to the boundary region BDA of the light emitting structure EMS. Some of the plurality of layers stacked in the light emitting structure EMS may be disconnected or bent by the first void VD1. For example, at least one charge generation layer and at least one hole injection layer included in the light emitting structure EMS may be disconnected by the first void VD1. In this way, due to the undercut shapes UDT1 to UDT3, portions of the light emitting structure EMS included in the first to third sub-pixels SP1 to SP3 may be at least partially disconnected.

The light emitting structure EMS may be arranged on the upper surface ATS1 of each of the first to third anode electrodes AE1 to AE3 exposed by the openings PDL_OP1 to PDL_OP3. The light emitting structure EMS may be in contact with the upper surface ATS1 of each of the first to third anode electrodes AE1 to AE3. The light emitting structure EMS may fill the openings PDL_OP1 to PDL_OP3 of the pixel definition layer PDL and may be arranged entirely over (e.g., over the entirety of) the first to third sub-pixels SP1 to SP3. As described above, the light emitting structure EMS may be partially disconnected or bent at a portion adjacent to the boundary region BDA by the undercut shapes UDT1 to UDT3. Accordingly, during an operation of the display panel DP, a current flowing from each of the first to third sub-pixels SP1 to SP3 to the neighboring sub-pixel through the layers included in the light emitting structure EMS may be reduced. Accordingly, the first to third light emitting elements LD1 to LD3 may operate with relatively high reliability.

The cathode electrode CE may be arranged on the light emitting structure EMS. The cathode electrode CE may be provided in common to the first to third sub-pixels SP1 to SP3. The cathode electrode CE may function as a half mirror that partially transmits light emitted from the light emitting structure EMS therethrough and partially reflects the light.

The first anode electrode AE1, a portion of the light emitting structure EMS overlapping the first anode electrode AE1, and a portion of the cathode electrode CE overlapping the first anode electrode AE1 may constitute the first light emitting element LD1. The second anode electrode AE2, a portion of the light emitting structure EMS overlapping the second anode electrode AE2, and a portion of the cathode electrode CE overlapping the second anode electrode AE2 may constitute the second light emitting element LD2. The third anode electrode AE3, a portion of the light emitting structure EMS overlapping the third anode electrode AE3, and a portion of the cathode electrode CE overlapping the third anode electrode AE3 may constitute the third light emitting element LD3.

An encapsulation layer TFE may be arranged on the cathode electrode CE. The encapsulation layer TFE may prevent or reduce the likelihood of oxygen, moisture, and/or the like penetrating into the light emitting element layer LDL.

The optical function layer OFL may be arranged on the encapsulation layer TFE. In one or more embodiments, the optical function layer OFL may be attached to the encapsulation layer TFE through an adhesive layer APL. For example, the optical function layer OFL may be formed separately and attached to the encapsulation layer TFE through the adhesive layer APL. The adhesive layer APL may further perform a function of protecting lower layers including the encapsulation layer TFE.

The optical function layer OFL may include a color filter layer CFL and a lens array LA. The color filter layer CFL may include first to third color filters CF1 to CF3 respectively corresponding to the first to third sub-pixels SP1 to SP3. The first to third color filters CF1 to CF3 may be to transmit light in different wavelength ranges therethrough. For example, the first to third color filters CF1 to CF3 may respectively transmit red light, green light, and blue light therethrough.

In one or more embodiments, the first to third color filters CF1 to CF3 may partially overlap each other in the boundary region BDA. In one or more embodiments, the first to third color filters CF1 to CF3 may be separated from each other, and a black matrix may be provided between the first to third color filters CF1 to CF3.

The lens array LA may be arranged on the color filter layer CFL. The lens array LA may include first to third lenses LS1 to LS3 respectively corresponding to the first to third sub-pixels SP1 to SP3. The first to third lenses LS1 to LS3 may respectively output light emitted from the first to third light emitting elements LD1 to LD3 to intended paths, thereby increasing light emission efficiency.

The overcoat layer OC may be arranged on the lens array LA. The overcoat layer OC may be configured to protect layers under the overcoat layer OC from foreign substances, such as dust, moisture, and/or the like. The cover window CW may be arranged on the overcoat layer OC.

FIG. 8 is an enlarged view illustrating a region A of FIG. 7, according to one or more embodiments of the present disclosure.

Referring to FIGS. 6 and 8, the pixel definition layer PDL may include first to third portions P1 to P3. The first portions P1 may overlap the first to third anode electrodes AE1 to AE3 and may not overlap the sacrificial patterns SCP1 to SCP3. The second portions P2 may overlap the first to third anode electrodes AE1 to AE3 and the sacrificial patterns SCP1 to SCP3. The third portions P3 may not overlap the first to third anode electrodes AE1 to AE3 or the sacrificial patterns SCP1 to SCP3. For example, in the boundary region BDA between the second and third anode electrodes AE2 and AE3, the first portions P1 may overlap the second and third anode electrodes AE2 and AE3 and may not overlap 2_2nd and 3_1st sacrificial patterns SCP2_2 to SCP3_1. The second portions P2 may overlap the second and third anode electrodes AE2 and AE3 and the 2_2nd and the 3_1st sacrificial patterns SCP2_2 to SCP3_1. The third portions P3 may not overlap the second and third anode electrodes AE2 and AE3 or the 2_2nd and the 3_1st sacrificial patterns SCP2_2 to SCP3_1.

The first and second portions P1 and P2 may protrude in the first direction DR1 or in an opposite direction of the first direction DR1 (e.g., which may also be referred to as the negative first direction −DR1) from the third portions P3. The first portions P1 may protrude in the first direction DR1 or in the opposite direction of the first direction DR1 from the second portions P2. The first and second portions P1 and P2 may protrude in the first direction DR1 and in the opposite direction of the first direction DR1 from the third portions P3. For example, in the boundary region BDA, a 1_1st portion P1_1 may protrude in the opposite direction of the first direction DR1 from the 2_1st portion P2_1 overlapping the 2_2nd sacrificial pattern SCP2_2. The 1_2nd portion P1_2 may protrude in the first direction DR1 from a 2_2nd portion P2_2 overlapping a 3_1st sacrificial pattern SCP3_1.

The first portions P1 and the first to third anode electrodes AE1 to AE3 may have an interval SAP designating a distance by which the first portions P1 and the first to third anode electrodes AE1 to AE3 are separated from each other. For example, the 1_1st portion P1_1 and the second anode electrode AE2 may have the interval SAP by which the the 1_1st portion P1_1 and the second anode electrode AE2 are spaced and/or separated from each other. The 1_2nd portion P1_2 and the third anode electrode AE3 may have the interval SAP by which the 1_2nd portion P1_2 and the third anode electrode AE3 are spaced and/or separated from each other. The sacrificial patterns SCP1 to SCP3 may be arranged between the second portions P2 and the first to third anode electrodes AE1 to AE3. For example, the 2_2nd sacrificial pattern SCP2_2 may be arranged between the 2_1st portion P2_1 and the second anode electrode AE2. The 3_1st sacrificial pattern SCP3_1 may be arranged between the 2_2nd portion P2_2 and the third anode electrode AE3.

In this way, the sum of the widths (in the first direction DR1) of the first and second portions P1 and P2 in the pixel definition layer PDL may be greater than the widths of the sacrificial patterns SCP1 to SCP3. For example, the 3_1st sacrificial pattern SCP3_1 may have a first width WD1 in the first direction DR1. In the pixel definition layer PDL adjacent to the 3_1st sacrificial pattern SCP3_1, the 1_2nd portion P1_2 may have a second width WD2 in the first direction DR1. The 2_2nd portion P2_2 may have a third width WD3 in the first direction DR1. The third width WD3 of the 2_2nd portion P2_2 may be equal to the first width WD1 of the 3_1st sacrificial pattern SCP3_1. The sum of the second width WD2 of the 1_2nd portion P1_2 and the third width WD3 of the 2_2nd portion P2_2 may be greater than the first width WD1 of the 3_1 sacrificial pattern SCP3_1.

During a manufacturing process, the pixel definition layer PDL may be undercut so as to overlap the first to third anode electrodes AE1 to AE3 and not to overlap the sacrificial patterns SCP1 to SCP3. For example, the first portions P1 of the pixel definition layer PDL may have the shape of eaves on (e.g., overhanging) the first to third anode electrodes AE1 to AE3.

In the second sub-pixel SP2, the 1_1st portion P1_1 of the pixel definition layer PDL and a first side SSF1 of the 2_2nd sacrificial pattern SCP2_2 may have a 2_2nd undercut shape UDT2_2. The 2_2nd undercut shape UDT2_2 may be provided as a single separator (e.g., to separate the light emitting structure EMS included in the second sub-pixel SP2 from adjacent sub-pixels). Accordingly, a 1_2nd void VD1_2 adjacent to the 1_1st portion P1_1 of the pixel definition layer PDL in the light emitting structure EMS may be formed. In the third sub-pixel SP3, the 1_2nd portion P1_2 of the pixel definition layer PDL and a second side SSF2 of the 3_1st sacrificial pattern SCP3_1 may have a 3_1st undercut shape UDT3_1. The 3_1st undercut shape UDT3_1 may be provided as a separator (e.g., to separate the light emitting structure EMS included in the third sub-pixel SP3 from adjacent sub-pixels). Accordingly, a 1_3rd void VD1_3 adjacent to the 1_2nd portion P1_2 of a pixel definition layer PDL in the light emitting structure EMS may be formed.

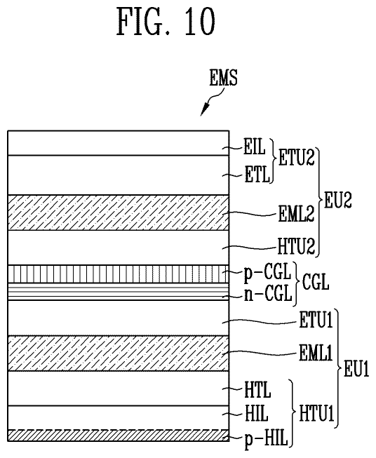

Some of the plurality of layers stacked in the light emitting structure EMS may be partially disconnected by the 1_2nd void VD1_2 and the 1_3rd void VD1_3. For example, at least one charge generation layer CGL (see, e.g., FIG. 10) and at least one hole injection layer HIL (see, e.g., FIG. 10) included in the light emitting structure EMS may be disconnected or bent by the 1_2nd void VD1_2 and the 1_3rd void VD1_3. In this way, portions of the light emitting structure EMS included in the first to third sub-pixels SP1 to SP3 may be at least partially separated from each other by the undercut shapes UDT1 to UDT3.

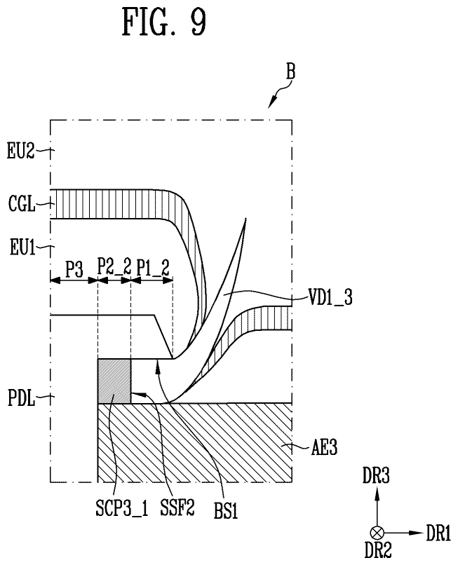

FIG. 9 is an enlarged view illustrating a region B of FIG. 8, according to one or more embodiments of the present disclosure.

Referring to FIGS. 7, 8 and 9, the light emitting structure EMS may be partially disconnected in regions adjacent to the first portions P1 of the pixel definition layer PDL protruding more than (e.g., extending beyond) the sacrificial patterns SCP1 to SCP3.

In one or more embodiments, the light emitting structure EMS may include a first light emitting portion EU1, the charge generation layer CGL, and a second light emitting portion EU2 which are sequentially stacked in the third direction DR3. For example, the first light emitting portion EU1 may be arranged on a corresponding third anode electrode AE3 and the pixel definition layer PDL. The charge generation layer CGL may be arranged on the first light emitting portion EU1. The second light emitting portion EU2 may be arranged on the charge generation layer CGL. In one or more embodiments, the cathode electrode CE may be arranged on the second light emitting portion EU2.

Referring to FIG. 9, the first light emitting portion EU1 may be partially disconnected in a region adjacent to the 1_2nd portion P1_2 of the pixel definition layer PDL. The first light emitting portion EU1 may be formed by depositing a base material of the first light emitting portion EU1. In such embodiments, the 1_2nd portion P1_2 may protrude more than the second side SSF2 of the 3_1st sacrificial pattern SCP3_1, and the 1_2nd portion P1_2 and the third anode electrode AE3 may have an interval therebetween separating the 1_2nd portion P1_2 and the third anode electrode AE3 from each other in the third direction DR3. Therefore, a base material of the first light emitting portion EU1 may not be deposited on the one side BS1 of the 1_2nd portion P1_2 that is adjacent to the third anode electrode AE3 and the second side SSF2 of the 3_1st sacrificial pattern SCP3_1. The first light emitting portion EU1 may not be formed in a region adjacent to the one side BS1 of the 1_2nd portion P1_2 and the second side SSF2 of the 3_1st sacrificial pattern SCP3_1.

The charge generation layer CGL may be formed on the first light emitting portion EU1 and may be partially disconnected in a region adjacent to the 1_2nd portion P1_2 of the pixel definition layer PDL. The charge generation layer CGL may be formed by depositing a base material of the charge generation layer CGL. The base material of a charge generation layer CGL may not be deposited on one side BS1 of the 1_2nd portion P1_2 adjacent to the third anode electrode AE3 and the second side SSF2 of the 3_1st sacrificial pattern SCP3_1. The charge generation layer CGL may not be formed in the region adjacent to one side BS1 of the 1_2nd portion P1_2 and the second side SSF2 of the 3_1st sacrificial pattern SCP3_1.

In this way, due to the 1_2nd portion P1_2 protruding more than (e.g., extending beyond) the 3_1st sacrificial pattern SCP3_1, discontinuity, such as the 1_3rd void VD1_3, may be formed in the first light emitting portion EU1 and the charge generation layer CGL. By forming discontinuity, such as the 1_3rd void VD1_3 in the light emitting structure EMS, the first light emitting portion EU1 and the charge generation layer CGL may be at least partially disconnected or bent.

FIG. 9 illustrates an example of a tandem structure in which the first and second light emitting portions EU1 and EU2 are stacked, but the present disclosure is not limited thereto. For example, the light emitting structure EMS may include one light emitting unit. The light emitting structure EMS may have a structure in which a hole injection layer, a hole transfer layer, a light emitting layer, an electron transfer layer, and an electron injection layer are sequentially arranged on the first to third anode electrodes AE1 to AE3 in the third direction DR3. In such embodiments, at least one hole injection layer adjacent to the first to third anode electrodes AE1 to AE3 may be partially disconnected due to discontinuity, such as the 1_3rd void VD1_3. For example, a p-hole injection layer p-HIL (see, e.g., FIG. 10) may be partially disconnected.

FIG. 10 is a cross-sectional view illustrating a part of a light emitting structure included in one of the first to third light emitting elements LD1 to LD3 of FIG. 7 according to one or more embodiments of the present disclosure.

Referring to FIG. 10, the light emitting structure EMS may have a tandem structure in which the first and second light emitting units EU1 and EU2 are stacked. The first to third light emitting elements LD1 to LD3 of FIG. 7 may have substantially the same light emitting structure EMS.

The first and second light emitting units EU1 and EU2 may each include at least one light emitting layer that generates light according to an applied current. The first light emitting unit EU1 may include a first light emitting layer EML1, a first electron transfer unit ETU1, and a first hole transfer unit HTU1. The first emitting layer EML1 may be arranged between the first electron transfer unit ETU1 and the first hole transfer unit HTU1. The second emitting unit EU2 may include a second emitting layer EML2, a second electron transfer unit ETU2, and a second hole transfer unit HTU2. The second emitting layer EML2 may be arranged between the second electron transfer unit ETU2 and the second hole transfer unit HTU2.

The first and second hole transfer units HTU1 and HTU2 may each include at least one of a hole injection layer HIL and/or a hole transfer layer HTL. In one or more embodiments, the first and second hole transfer units HTU1 and HTU2 may each further include a hole buffer layer, an electron blocking layer, and/or the like, as desired and/or needed. The first and second hole transfer units HTU1 and HTU2 may have either the same configuration or different configurations.

The first hole transport unit HTU1 may include a p-hole injection layer p-HIL doped with a p-type (kind) dopant in a suitable hole injection material. For example, the p-hole injection layer p-HIL may be arranged between the first to third anode electrodes AE1 to AE3 and the hole transfer layer HTL. This p-hole injection layer p-HIL may perform a function of smoothly injecting holes transferred from each of the first to third anode electrodes AE1 to AE3. However, in FIG. 10, the p-hole injection layer (p-HIL) is illustrated as a single layer within the hole injection layer (HIL), but the embodiments are not limited thereto. For example, the hole injection layer (HIL) may be a p-hole injection layer (p-HIL).

Each of the first and second electron transfer units ETU1 and ETU2 may include at least one of an electron injection layer EIL and/or an electron transfer layer ETL. In one or more embodiments, the first and second electron transfer units ETU1 and ETU2 may each further include an electron buffer layer, a hole blocking layer, and/or the like, as desired and/or needed. The first and second electron transfer units ETU1 and ETU2 may have either the same configuration or different configurations.

A connection layer, which may be provided in the form of the charge generation layer CGL, may be arranged between the first light emitting unit EU1 and the second light emitting unit EU2 to connect the first light emitting unit EU1 to the second light emitting unit EU2. In one or more embodiments, the charge generation layer CGL may include an n-type (kind) electron generation layer n-CGL for supplying electrons to the first light emitting unit EU1 and a p-type (kind) charge generation layer p-CGL for supplying holes to the second light emitting unit EL2. For example, the n-type (kind) electron generation layer n-CGL may include an alkali metal, an alkaline earth metal, a lanthanide metal, and/or a (e.g., any suitable) combination thereof. The p-type (kind) charge generation layer p-CGL may include a p-type (kind) dopant, such as hexaazatriphenylenehexacarbonitrile (HAT-CN), tetracyanoquinodimethane (TCNQ), and/or 2-(7-dicyanomethylene-1,3,4,5,6,8,9,10-octafluoro-7H-pyrene-2-ylidene)-malononitrile (NDP-9). However, the present disclosure is not limited thereto.

In one or more embodiments, the first light emitting layer EML1 and the second light emitting layer EML2 may generate lights of different colors. The light emitted from the first light emitting layer EML1 and the light emitted from the second light emitting layer EML2 may be mixed together and recognized as white light. For example, the first light emitting layer EML1 may generate blue light, and the second light emitting layer EML2 may generate yellow light. In one or more embodiments, the second light emitting layer EML2 may include a structure in which a first sub-light emitting layer configured to generate red light and a second sub-light emitting layer configured to generate green light are stacked. The red light and the green light may be mixed together to provide yellow light. In this case, an intermediate layer configured to perform a function of transferring holes and/or a function of blocking the transfer of electrons may be further arranged between the first and second sub-light emitting layers. In one or more embodiments, the first emitting layer EML1 and the second emitting layer EML2 may generate the same light of color.

The light emitting structure may be formed by using a method, such as vacuum deposition, or inkjet printing, but the present disclosure is not limited thereto.

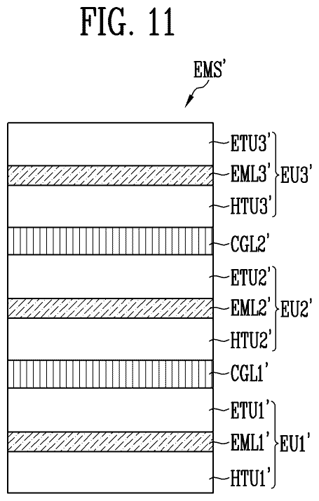

FIG. 11 is a cross-sectional view illustrating a part of the light emitting structure included in any one of the first to third emitting elements LD1 to LD3 of FIG. 7, according to one or more embodiments of the present disclosure.

Referring to FIG. 11, the light emitting structure may have a tandem structure in which first to third emitting units EU1′ to EU3′ are stacked. The light emitting structures of the first to third emitting elements LD1 to LD3 of FIG. 7 may be configured substantially the same as each other.

The first to third light emitting units EU1′ to EU3′ may each include a light emitting layer that generates light according to an applied current. The first light emitting unit EU1′ may include a first light emitting layer EML1′, a first electron transfer unit ETU1′, and a first hole transfer unit HTU1′. The first light emitting layer EML1′ may be arranged between the first electron transfer unit ETU1′ and the first hole transfer unit HTU1′. The second light emitting unit EU2′ may include a second light emitting layer EML2′, a second electron transfer unit ETU2′, and a second hole transfer unit HTU2′. The second light emitting layer EML2′ may be arranged between the second electron transfer unit ETU2′ and the second hole transfer unit HTU2′. The third light emitting unit EU3′ may include a third light emitting layer EML3′, a third electron transfer unit ETU3′, and a third hole transfer unit HTU3′. The third light emitting layer EML3′ may be arranged between the third electron transfer unit ETU3′ and the third hole transfer unit HTU3′.

The first to third hole transfer units HTU1′ to HTU3′ may each include at least one of a hole injection layer and/or a hole transfer layer and may further include a hole buffer layer, an electron blocking layer, and/or the like, as desired and/or needed. The first to third hole transfer units HTU1′ to HTU3′ may have either the same configuration or different configurations.

The first to third electron transfer units ETU1′ to ETU3′ may each include at least one of an electron injection layer and/or an electron transfer layer and may further include an electron buffer layer, a hole blocking layer, and/or the like, as desired and/or needed. The first to third electron transfer units ETU1′ to ETU3′ may have either the same configuration or different configurations.

A first charge generation layer CGL1′ may be arranged between the first light emitting unit EU1′ and the second light emitting unit EU2′. A second charge generation layer CGL2′ may be arranged between the second light emitting unit EU2′ and the third light emitting unit EU3′.

In one or more embodiments, the first to third light emitting layers EML1′ to EML3′ may generate light of different colors. The light emitted from the first light emitting layer EML1′ to the light emitted from the third light emitting layer EML3′ may be mixed together and recognized as white light. For example, the first light emitting layer EML1′ may generate blue light, the second light emitting layer EML2′ may generate green light, and the third light emitting layer EML3′ may generate red light.

In one or more embodiments, two or more of the first to third light emitting layers EML1′ to EML3′ may generate light of the same color.

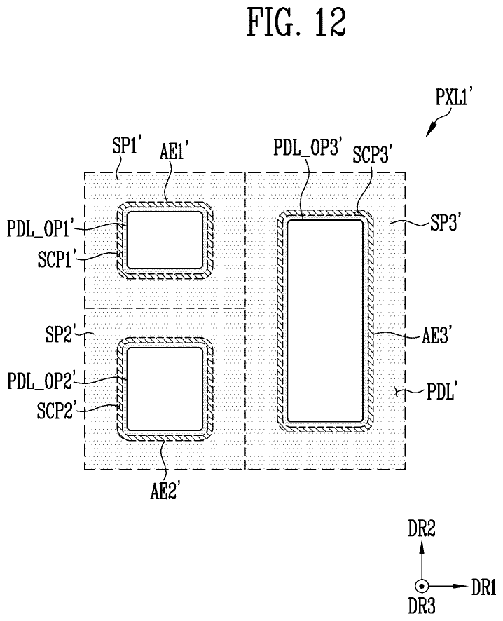

FIG. 12 is a plan view illustrating a pixel according to one or more embodiments of the present disclosure.

Referring to FIG. 12, a first pixel PXL1′ may include first to third sub-pixels SP1′ to SP3′.

The first sub-pixel SP1′ may include a first anode electrode AE1′, a first sacrificial pattern SCP1′, and a pixel definition layer PDL′ around the first anode electrode AE1′. The first sacrificial pattern SCP1′ may be arranged along an edge (e.g., outer edge) of the first anode electrode AE1′ to be around (e.g., surround) a first opening PDL_OP1′ of the pixel definition layer PDL′.

The second sub-pixel SP2′ may include a second anode electrode AE2′, a second sacrificial pattern SCP2′, and a pixel definition layer PDL′ around the second anode electrode AE2′. The second sacrificial pattern SCP2′ may be arranged along an edge (e.g., outer edge) of the second anode electrode AE2′ to be around (e.g., surround) a second opening PDL_OP2′ of the pixel definition layer PDL′.

The third sub-pixel SP3′ may include a third anode electrode AE3′, a third sacrificial pattern SCP3′, and a pixel definition layer PDL′ around the third anode electrode AE3′. The third sacrificial pattern SCP3′ may be arranged along an edge (e.g., outer edge) of the third anode electrode AE3′ to be around (e.g., surround) a third opening PDL_OP3′ of the pixel definition layer PDL′.

The first sub-pixel SP1′ and the second sub-pixel SP2′ may be arranged in the second direction DR2. The third sub-pixel SP3′ may be arranged in the first direction DR1 with respect to each of the first and second sub-pixels SP1′ and SP2′.

The second sub-pixel SP2′ may have a greater area than the first sub-pixel SP1′, and the third sub-pixel SP3′ may have a greater area than the second sub-pixel SP2′. Accordingly, the second anode electrode AE2′ may have a greater area than the first anode electrode AE1′, and the third anode electrode AE3′ may have a greater area than the second anode electrode AE2′. However, the present disclosure is not limited thereto. For example, the first and second sub-pixels SP1′ and SP2′ may have substantially the same area, and the third sub-pixel SP3′ may have a greater area than each of the first and second sub-pixels SP1′ and SP2′. In this way, areas of the first to third sub-pixels SP1′ to SP3′ may be variously modified according to one or more embodiments.

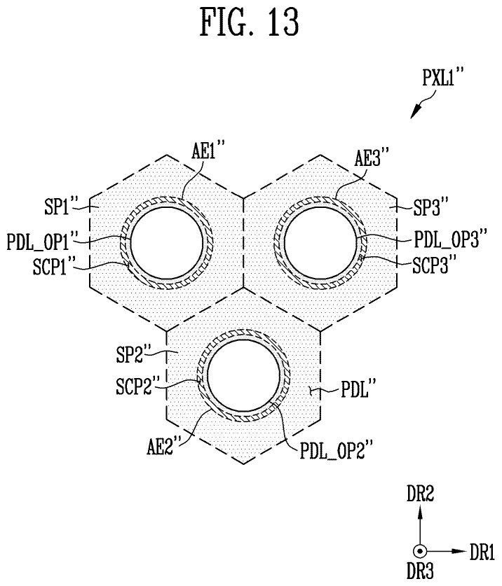

FIG. 13 is a plan view illustrating a pixel, according to one or more embodiments of the present disclosure.

Referring to FIG. 13, a first sub-pixel SP1″ may include a first anode electrode AE1″, a first sacrificial pattern SCP1″, and a pixel definition layer PDL″ around the first anode electrode AE1″. The second sub-pixel SP2″ may include a second anode electrode AE2″, a second sacrificial pattern SCP2″, and a pixel definition layer PDL″ around the second anode electrode AE2″. The third sub-pixel SP3″ may include a third anode electrode AE3″, a third sacrificial pattern SCP3″, and a pixel definition layer PDL″ around the third anode electrode AE3″.

The first, second, and third sub-pixels SP1″, SP2″, and SP3″ may have polygonal shapes when viewed in the third direction DR3. For example, the shapes of the first to third sub-pixels SP1″ to SP3″ may each be a hexagon, as illustrated in FIG. 13.

The first to third anode electrodes AE1″ to AE3″ may have circular shapes when viewed in the third direction DR3. However, the present disclosure is not limited thereto. For example, the first to third anode electrodes AE1″ to AE3″ may each have a polygonal shape.

The first and third sub-pixels SP1″ and SP3″ may be arranged in the first direction DR1. The second sub-pixel SP2″ may be arranged in a direction (or a diagonal direction) that is inclined at an acute angle from the second direction DR2 with respect to the first sub-pixel SP1″.

The arrangements of the sub-pixels illustrated in FIGS. 6, 12, and 13 are examples, and the present disclosure is not limited thereto. Each pixel may include two or more sub-pixels, and the sub-pixels may be arranged in one or more suitable ways and may have one or more suitable shapes, and light emitting regions thereof may also have one or more suitable shapes.

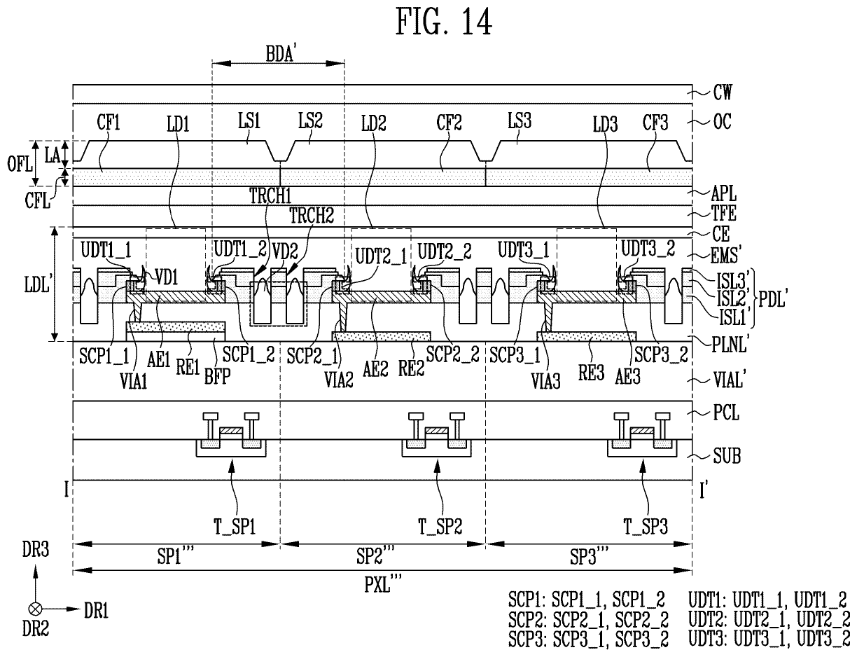

FIG. 14 is a cross-sectional view taken along the line I-I′ of FIG. 6 according to one or more embodiments of the present disclosure.

Referring to FIG. 6 and FIG. 14, a pixel circuit layer PCL, a via layer VIAL′, a light emitting element layer LDL′, an encapsulation layer TFE, an adhesive layer APL, an optical function layer OFL, an overcoat layer OC, and a cover window CW may be sequentially arranged on the substrate SUB in the third direction DR3.

The substrate SUB, the pixel circuit layer PCL, the via layer VIAL′, the light emitting element layer LDL′, the encapsulation layer TFE, the adhesive layer APL, the optical function layer OFL, the overcoat layer OC, and the cover window CW may be configured as described with reference to FIG. 7. Hereinafter, like reference numbers refer to like elements and redundant descriptions may not be provided.

The pixel definition layer PDL′ may include an additional separator such that the light emitting structure EMS′ further includes discontinuity in a boundary region BDA′. In one or more embodiments, the pixel definition layer PDL′ may include one or more trenches in the boundary region BDA′ as one or more separators.

In one or more embodiments, a first trench TRCH1 and a second trench TRCH2 may penetrate the pixel definition layer PDL′ and partially penetrate a planarization layer PLNL′. In one or more embodiments, the first and second trenches TRCH1 and TRCH2 may penetrate the pixel definition layer PDL′ and the planarization layer PLNL′ and partially penetrate the via layer VIAL′. In one or more embodiments, the first and second trenches TRCH1 and TRCH2 may at least partially penetrate the planarization layer PLNL′ and/or the via layer VIAL′, and a part of the pixel definition layer PDL′ may be arranged in the first and second trenches TRCH1 and TRCH2.

FIG. 14 illustrates that the first and second trenches TRCH1 and TRCH2 are provided in the boundary region BDA′. However, te present disclosure is not limited thereto. For example, the pixel definition layer PDL′ may include one trench in the boundary region BDA′.

Due to the first and second trenches TRCH1 and TRCH2, discontinuity, such as a second void VD2, may be formed in a light emitting structure EMS′ in the boundary region BDA′. Some of a plurality of layers stacked in the light emitting structure EMS′ may be disconnected or bent by the second void VD2. For example, at least one charge generation layer and at least one hole injection layer included in the light emitting structure EMS′ may be disconnected by the second void VD2. In this way, by additionally forming the first and second trenches TRCH1 and TRCH2, portions of the light emitting structure EMS′ which are included in the first to third sub-pixels SP1 to SP3 may be more reliably and partially separated from each other.

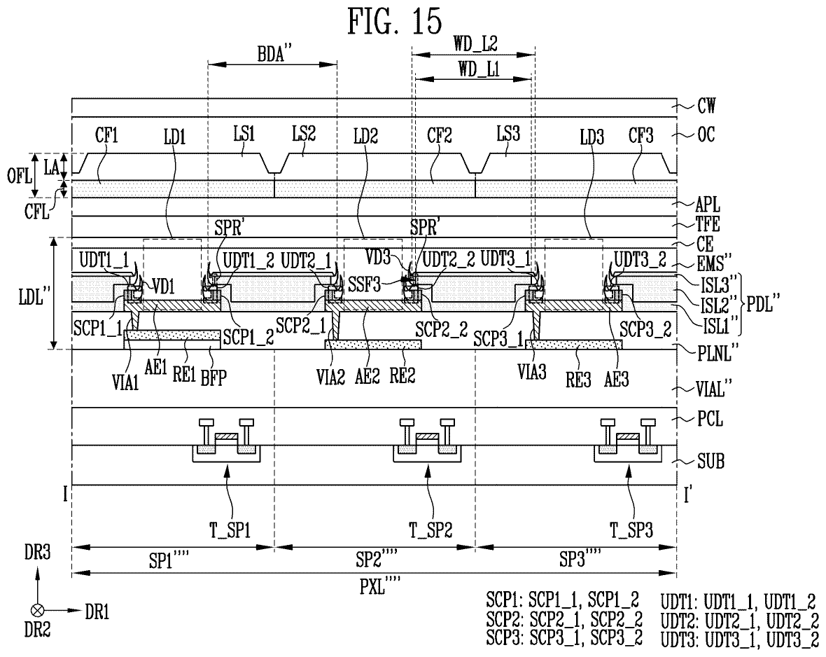

FIG. 15 is a cross-sectional view taken along the line I-I′ of FIG. 6 according to one or more embodiments of the present disclosure.

Referring to FIG. 6 and FIG. 15, a pixel circuit layer PCL, a via layer VIAL″, a light emitting element layer LDL″, an encapsulation layer TFE, an adhesive layer APL, an optical function layer OFL, an overcoat layer OC, and a cover window CW may be sequentially arranged on a substrate SUB in the third direction DR3.

The substrate SUB, the pixel circuit layer PCL, the via layer VIAL″, the light emitting element layer LDL″, the encapsulation layer TFE, the adhesive layer APL, the optical function layer OFL, the overcoat layer OC, and the cover window CW may be configured in substantially the same manner as described with reference to FIG. 7. Hereinafter, like reference numbers refer to like elements and redundant descriptions may not be provided.

A pixel definition layer PDL″ may include an additional separator such that a light emitting structure EMS″ further includes discontinuity adjacent to a boundary region BDA″. The pixel definition layer PDL″ may include a first insulating layer ISL1″ including first, second, and third portions P1, P2, and P3. A second insulating layer ISL2″ may be arranged on the first insulating layer ISL1″. A third insulating layer ISL3″ may be arranged on the second insulating layer ISL2″. In one or more embodiments, the third insulating layer ISL3″ of the pixel definition layer PDL″ may have a width greater than a width of the second insulating layer ISL2″ arranged directly under the third insulating layer ISL3″. For example, the pixel definition layer PDL″ may have a cross-section of a “T” shape or an “I” shape in the boundary region BDA″.

On undercut shapes UDT1 to UDT3 due to sacrificial patterns SCP1 to SCP3, third side surfaces SSF3 of the second insulating layer ISL2″ may be provided as separators SPR′. Accordingly, a third void VD3 adjacent to the third side surface SSF3 of the second insulating layer ISL2″ may be formed in the light emitting structure EMS″.

Some of a plurality of layers stacked in the light emitting structure EMS″ may be disconnected or bent by the third void VD3. For example, at least one charge generation layer included in the light emitting structure EMS″ may be disconnected from at least one hole injection layer included in the light emitting structure EMS″ by the third void VD3. In this way, due to the separators SPR′, portions of the light emitting structure EMS″ included in the first to third sub-pixels SP1 to SP3 may be at least partially separated from each other.

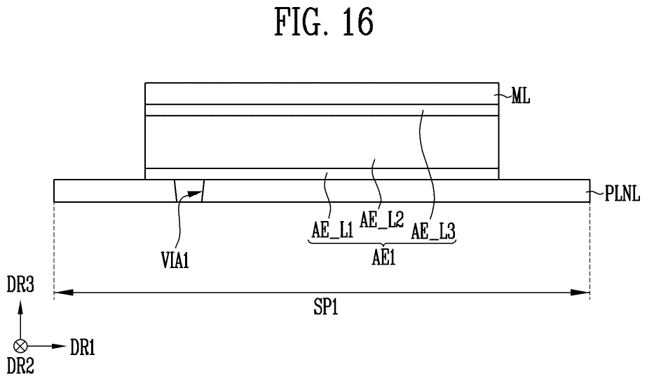

FIGS. 16 to 19 are cross-sectional views schematically illustrating a method of manufacturing a display device, according to one or more embodiments of the present disclosure.

Hereinafter, the method of manufacturing a display device described above with reference to FIG. 7 will be described with reference to FIGS. 16 to 19. In describing FIGS. 16 to 19, descriptions previously made with reference to FIG. 7 may not be provided.

FIGS. 16 to 19 illustrate only the first sub-pixel SP1 for the sake of convenience of description, but the second and third sub-pixels SP2 and SP3 (see, e.g., FIG. 7) may also be manufactured in substantially the same manner as the first sub-pixel SP1.

In one or more embodiments, the pixel circuit layer PCL (see, e.g., FIG. 7) on the substrate SUB (see, e.g., FIG. 7) may be formed through a generally available and/or generally utilized process for manufacturing a semiconductor device. For example, a conductive layer or an insulating layer included in the pixel circuit layer PCL may be formed by a photolithography process. In one or more embodiments, the conductive layer or insulating layer included in the pixel circuit layer PCL may be etched by one or more suitable methods (wet etching, dry etching, and/or the like) and may be deposited by one or more suitable methods (sputtering, chemical vapor deposition, and/or the like). However, the present disclosure is not limited thereto.

Referring to FIG. 16, a first anode electrode AE1 may be formed. The first anode electrode AE1 may be formed on a planarization layer PLNL. The first anode electrode AE1 may be connected to the first reflective electrode RE1 (see, e.g., FIG. 7) through a first via VIA1 passing through the planarization layer PLNL.

In one or more embodiments, the first anode electrode AE1 may include a first anode electrode layer AE_L1, a second anode electrode layer AE_L2, and a third anode electrode layer AE_L3. The first anode electrode layer AE_L1 may be arranged on the planarization layer PLNL. The second anode electrode layer AE_L2 may be arranged on the first anode electrode layer AE_L1. The third anode electrode layer AE_L3 may be arranged on the second anode electrode layer AE_L2. For example, a thickness of each of the first to third anode electrode layers AE_L1 to AE_L3 may be 100 Angstoms (Å), 500 Å, or 1000 Å, but the present disclosure is not limited thereto.

The first anode electrode AE1 may be arranged as a multilayer including the first to third anode electrode layers AE_L1 to AE_L3. The first to third anode electrode layers AE_L1 to AE_L3 may each include titanium (Ti), aluminum (Al), and/or titanium nitride (TiN). However, the present disclosure is not limited thereto. For example, the first to third anode electrode layers AE_L1 to AE_L3 may each include at least one transparent conductive material.

A metal layer ML may be formed on the first anode electrode AE1. The metal layer ML may be formed on the third anode electrode layer AE_L3. For example, a thickness of the metal layer ML arranged on the third anode electrode layer AE_L3 may be 30 Å, but the present disclosure is not limited thereto.

The metal layer ML may include at least one conductive material. For example, the metal layer ML may be aluminum (Al), but the present disclosure is not limited thereto.

The first anode electrode AE1 and the metal layer ML may be formed by sequentially depositing corresponding conductive materials on the planarization layer PLNL and patterning the conductive materials through a photolithography process. In embodiments, the method of forming the first anode electrode AE1 and the metal layer ML is not limited. For example, one or more suitable manufacturing methods generally utilized and/or generally available in the art may be applied.

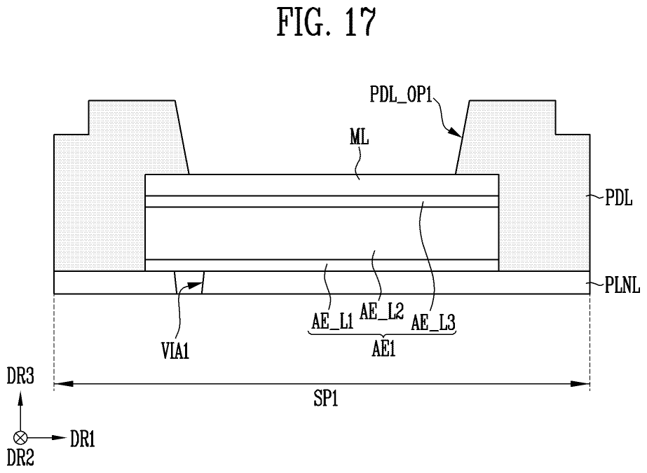

Referring to FIG. 17, a pixel definition layer PDL including a first opening PDL_OP1 exposing at least a part of the metal layer ML may be formed on the metal layer ML.

In one or more embodiments, the first opening PDL_OP1 of the pixel definition layer PDL may be formed through an etch process. For example, the pixel definition layer PDL may be dry-etched. Through dry etching, the first opening PDL_OP1, through which light is emitted from the light emitting structure EMS corresponding to the first sub-pixel SP1, may be formed in the pixel definition layer PDL.

In a process of etching the pixel definition layer PDL to form the first opening PDL_OP1, the metal layer ML may protect the first anode electrode AE1. For example, if (e.g., when) there is no metal layer ML, the first anode electrode AE1 may be unintentionally etched during the process of etching the pixel definition layer PDL. However, as the metal layer ML is arranged on the first anode electrode AE1, even if (e.g., when) the pixel definition layer PDL is unintentionally over-etched during the process of etching the pixel definition layer PDL, the metal layer ML may be etched instead of the first anode electrode AE1. Accordingly, the metal layer ML may protect the first anode electrode AE1 from damage during the process of forming the pixel definition layer PDL.

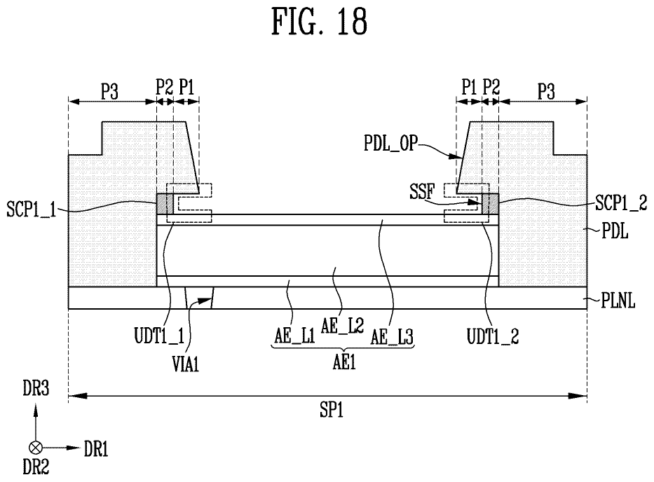

Referring to FIG. 18, the metal layer ML may be etched to form sacrificial patterns SCP1_1 and SCP1_2. An exposed portion of the metal layer ML may be etched at the first opening PDL_OP of the pixel definition layer PDL. Accordingly, at least a part of the first anode electrode AE1 may be exposed. For example, the metal layer ML may be wet-etched. Through wet-etching, the sacrificial patterns SCP1_1 and SCP1_2 between the first anode electrode AE1 and the pixel definition layer PDL may be formed from the metal layer ML.

The wet etching may include anisotropic etching and isotropic etching. For example, the metal layer ML may be wet-etched by using a tetramethylammonium hydroxide (TMAH) etching solution used for anisotropic wet etching. The TMAH etching solution may be a material that may etch aluminum (Al)-based metal materials. However, the etching solution may change depending on materials included in the metal layer ML and is not limited thereto.

For example, the third anode electrode layer AE_L3 of the first anode electrode AE1 may include a material with etch selectivity with respect to the sacrificial patterns SCP1_1 and SCP1_2. Accordingly, the first anode electrode AE1 may not be etched in the process of etching the sacrificial patterns SCP1_1 and SCP1_2. Accordingly, side surfaces SSF of the sacrificial patterns SCP1_1 and SCP1_2 may have first undercut shapes UDT1_1 and UDT1_2 in cross-sections relative to the first portions P1 of the pixel definition layer PDL. For example, because an etch rate of the metal layer ML on the etching solution is greater than an etch rate of the pixel definition layer PDL, the metal layer ML may be mainly etched. Accordingly, in a cross-section, the sacrificial patterns SCP1_1 and SCP1_2 may be formed between the first anode electrode AE1 and the second portions P2 of the pixel definition layer PDL. In one or more embodiments, the first portions P1 of the pixel definition layer PDL may be formed to protrude in the first direction DR1 or in an opposite direction of the first direction DR1 (e.g., the negative first direction-DR1) more than the sacrificial patterns SCP1_1 and SCP1_2.

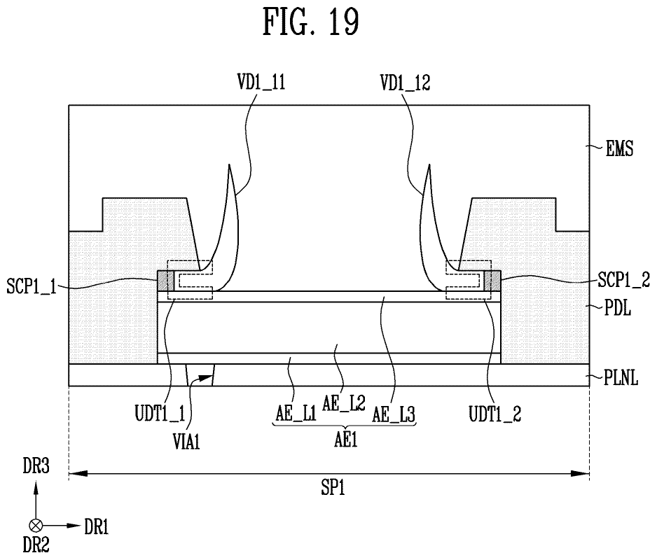

Referring to FIG. 19, a light emitting structure EMS may be formed on the first anode electrode AE1 and the pixel definition layer PDL.

In one or more embodiments, the light emitting structure EMS may be formed on an exposed portion of the first anode electrode AE1. The light emitting structure EMS may be formed through a process, such as vacuum deposition or inkjet printing. Due to the first undercut shapes UDT1_1 and UDT1_2, the light emitting structure EMS may not be formed in regions adjacent to the first portions P1 of the pixel definition layer PDL and the side surfaces SSF of the sacrificial patterns SCP1_1 and SCP1_2. Due to the first undercut shapes UDT1_1 and UDT1_2, discontinuity, such as first voids VD1_11 and VD1_12, may be formed in the light emitting structure EMS.

Some of a plurality of layers stacked in the light emitting structure EMS may be partially disconnected by the first voids VD1_11 and VD1_12. For example, if (e.g., when) the light emitting structure EMS is a tandem structure in which first and second light emitting units EU1 and EU2 are stacked, the first light emitting unit EU1 and the charge generation layer CGL may be at least partially disconnected or bent. For another example, if (e.g., when) the light emitting structure EMS is a structure including one light emitting unit, the p-hole injection layer p-HIL may be at least partially disconnected or bent. However, the present disclosure is not limited thereto.

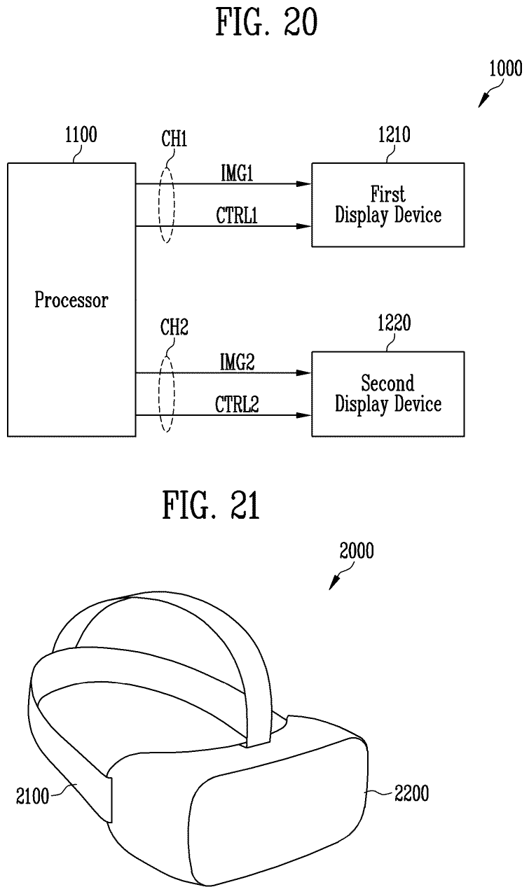

FIG. 20 is a block diagram illustrating a display system according to one or more embodiments of the present disclosure.

Referring to FIG. 20, a display system 1000 may include a processor 1100 and one or more display devices 1210 and 1220.

The processor 1100 may perform one or more suitable tasks and/or calculations. In one or more embodiments, the processor 1100 may include an application processor, a graphics processor, a microprocessor, a central processing unit (CPU), and/or the like. The processor 1100 may be connected to other components of the display system 1000 through a bus system and control the components.

FIG. 20 illustrates that the display system 1000 includes first and second display devices 1210 and 1220. The processor 1100 may be connected to the first display device 1210 through a first channel CH1 and to the second display device 1220 through a second channel CH2.

The processor 1100 may be to transmit first image data IMG1 and a first control signal CTRL1 to the first display device 1210 through the first channel CH1. The first display device 1210 may display an image based on the first image data IMG1 and the first control signal CTRL1. The first display device 1210 may be configured similarly to the display device DD described above with reference to FIG. 1. In such embodiments, the first image data IMG1 and the first control signal CTRL1 may be provided respectively as the input image data IMG and the control signal CTRL of FIG. 1.

The processor 1100 may be to transmit second image data IMG2 and a second control signal CTRL2 to the second display device 1220 through the second channel CH2. The second display device 1220 may display an image based on the second image data IMG2 and the second control signal CTRL2. The second display device 1220 may be configured similarly to the display device DD described above with reference to FIG. 1. In such embodiments, the second image data IMG2 and the second control signal CTRL2 may be provided respectively as the input image data IMG and the control signal CTRL of FIG. 1.

The display system 1000 may include a computing system, which provides an image display function, such as a portable computer, a mobile phone, a smartphone, a tablet personal computer, a smart watch, a watch phone, a portable multimedia player (PMP), a navigation system, or an ultramobile personal computer (UMPC). In one or more embodiments, the display system 1000 may include at least one of a head mounted display (HMD), a virtual reality (VR) device, a mixed reality (MR) device, and/or an augmented reality (AR) device.

FIG. 21 is a perspective view illustrating an example of an application of the display system 1000 of FIG. 20, according to one or more embodiments of the present disclosure.

Referring to FIG. 21, the display system 1000 of FIG. 20 may be applied to a head mounted display device 2000. The head mounted display device 2000 may be a wearable electronic device that may be worn on a user's head.

The head mounted display device 2000 may include a head mounted band 2100 and a display device storage case 2200. The head mounted band 2100 may be connected to the display device storage case 2200. The head mounted band 2100 may include a horizontal band and/or a vertical band for fixing the head mounted display device 2000 to a user's head. The horizontal band may be configured to be around (e.g., surround) a side portion of the user's head, and the vertical band may be configured to be around (e.g., surround) an upper portion of the user's head. However, the present disclosure is not limited thereto. For example, the head mounted band 2100 may also be implemented in the form of a glasses frame, a helmet, and/or the like.

The display device storage case 2200 may store the first and second display devices 1210 and 1220 of FIG. 20. The display device storage case 2200 may further store the processor 1100 of FIG. 20.

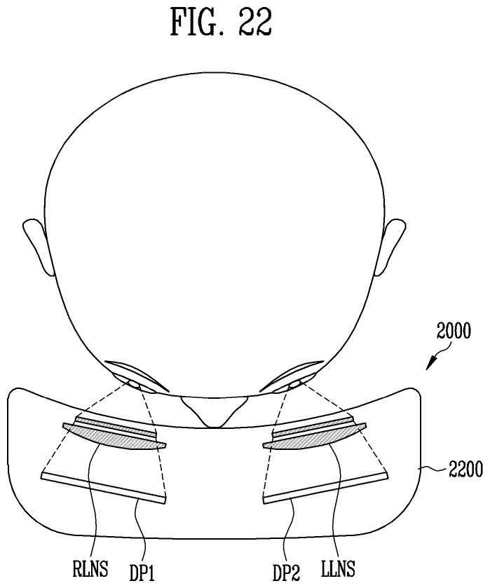

FIG. 22 is a view illustrating the head mounted display device of FIG. 21 worn by a user, according to one or more embodiments of the present disclosure.

Referring to FIG. 22, a first display panel DP1 of the first display device 1210 and a second display panel DP2 of the second display device 1220 are arranged in the head mounted display device 2000. The head mounted display device 2000 may further include one or more lenses, that is a right eye lens RLNS and a left eye lens LLNS.

In the display device storage case 2200, the right eye lens RLNS may be arranged between the first display panel DP1 and a user's right eye. In the display device storage case 2200, the left eye lens LLNS may be arranged between the second display panel DP2 and the user's left eye.

An image output from the first display panel DP1 may be shown to the user's right eye through the right eye lens RLNS. The right eye lens RLNS may refract the light from the first display panel DP1 toward the user's right eye. The right eye lens RLNS may perform an optical function for adjusting a viewing distance between the first display panel DP1 and the user's right eye.

An image output from the second display panel DP2 may be shown to the user's left eye through the left eye lens LLNS. The left eye lens LLNS may refract the light from the second display panel DP2 toward the user's left eye. The left eye lens LLNS may perform an optical function for adjusting a viewing distance between the second display panel DP2 and the user's left eye.

In one or more embodiments, each of the right eye lens RLNS and the left eye lens LLNS may include an optical lens having a cross-section in a pancake shape (e.g., a convex shape). In one or more embodiments, each of the right eye lens RLNS and the left eye lens LLNS may include a multi-channel lens including sub-regions with different optical characteristics. In such embodiments, each display panel outputs images corresponding to sub-regions of the multi-channel lens, and the output images may be shown to the user by passing through the corresponding sub-regions.

In the display device according to one or more embodiments of the present disclosure, a portion protruding more than (e.g., extending beyond) a sacrificial pattern is formed in a pixel definition layer arranged on an anode electrode, and accordingly, at least one charge generation layer and at least one hole injection layer included in the light emitting structure EMS may be partially disconnected. Accordingly, a current flowing out from each of the first to third sub-pixels SP1 to SP3 to a neighboring sub-pixel may be reduced. Therefore, according to one or more embodiments of the present disclosure, a lateral leakage phenomenon may be effectively improved, and thus, reliability may be increased.

According to aspects of embodiments of the present disclosure, a display device with increased reliability and a method of manufacturing the display device are provided.

The aspects according to one or more embodiments are not limited to the description made above, and more diverse aspects are included in spirit and scope of the present disclosure.

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

Further, the use of “may” when describing embodiments of the present disclosure refers to “one or more embodiments of the present disclosure.”

As used herein, the term “substantially,” “about,” and similar terms are used as terms of approximation and not as terms of degree, and are intended to account for the inherent deviations in measured or calculated values that would be recognized by those of ordinary skill in the art. “Substantially” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “substantially” may mean within one or more standard deviations, or within ±30%, 20%, 10%, 5% of the stated value.

The display device, electronic apparatus, method of manufacturing the display device, or any other relevant devices or components according to embodiments of the present disclosure described herein may be implemented utilizing any suitable hardware, firmware (e.g., an application-specific integrated circuit), software, or a combination of software, firmware, and hardware. For example, the various components of the device may be formed on one integrated circuit (IC) chip or on separate IC chips. Further, the various components of the device may be implemented on a flexible printed circuit film, a tape carrier package (TCP), a printed circuit board (PCB), or formed on one substrate. Further, the various components of the device may be a process or thread, running on one or more processors, in one or more computing devices, executing computer program instructions and interacting with other system components for performing the various functionalities described herein. The computer program instructions are stored in a memory which may be implemented in a computing device using a standard memory device, such as, for example, a random access memory (RAM). The computer program instructions may also be stored in other non-transitory computer readable media such as, for example, a CD-ROM, flash drive, or the like. Also, a person of skill in the art should recognize that the functionality of various computing devices may be combined or integrated into a single computing device, or the functionality of a particular computing device may be distributed across one or more other computing devices without departing from the scope of the embodiments of the present disclosure.

A person of ordinary skill in the art, in view of the present disclosure in its entirety, would appreciate that each suitable feature of the various embodiments of the present disclosure may be combined or combined with each other, partially or entirely, and may be technically interlocked and operated in various suitable ways, and each embodiment may be implemented independently of each other or in conjunction with each other in any suitable manner unless otherwise stated or implied.

It will be understood that descriptions of features or aspects within each embodiment should typically be considered as available for other similar features or aspects in other embodiments, unless otherwise described. Thus, as would be apparent to one of ordinary skill in the art, features, characteristics, and/or elements described in connection with a particular embodiment may be used singly or in combination with features, characteristics, and/or elements described in connection with other embodiments unless otherwise specifically indicated. It is to be understood that the foregoing is an illustration of various example embodiments and is not to be construed as limited to the specific embodiments disclosed herein, and that various modifications to the disclosed embodiments, as well as other example embodiments, are intended to be included within the spirit and scope of the present disclosure as defined in the appended claims, and their equivalents.

What is claimed is:

1. A display device comprising:
a substrate;
a pixel circuit layer on the substrate;
an anode electrode on the pixel circuit layer;
a pixel definition layer on the pixel circuit layer and having an opening that exposes at least a part of the anode electrode;
a sacrificial pattern in the opening, between the anode electrode and the pixel definition layer, and overlapping the anode electrode and the pixel definition layer;
a light emitting structure on the anode electrode and the pixel definition layer; and
a cathode electrode on the light emitting structure,
wherein the pixel definition layer comprises a first portion that overlaps the anode electrode and does not overlap the sacrificial pattern, a second portion that overlaps the anode electrode and the sacrificial pattern, and a third portion that does not overlap the anode electrode and the sacrificial pattern, and
the sacrificial pattern comprises a metal material.

2. The display device of claim 1, wherein the sacrificial pattern comprises aluminum (Al).

3. The display device of claim 1, wherein the light emitting structure is partially disconnected in a region adjacent to the first portion of the pixel definition layer.

4. The display device of claim 1, wherein the first portion of the pixel definition layer and a side surface of the sacrificial pattern together have an undercut shape.

5. The display device of claim 4, wherein the undercut shape is provided, on the anode electrode, by the first portion extending beyond the sacrificial pattern.

6. The display device of claim 1, wherein the sacrificial pattern is between the second portion and the anode electrode.

7. The display device of claim 1, wherein the first portion is separated by an interval from the anode electrode.

8. The display device of claim 1, wherein
the sacrificial pattern has a first width,
the first portion has a second width,
the second portion has a third width, and
a sum of the second width and the third width is greater than the first width.

9. The display device of claim 1, wherein
the light emitting structure comprises light emitting units that are sequentially stacked and a charge generation layer between the light emitting units, and
a light emitting unit adjacent to the anode electrode, among the light emitting units, is partially disconnected from the charge generation layer.

10. The display device of claim 1, wherein the light emitting structure comprises:
a hole injection layer on the anode electrode;
a hole transfer layer on the hole injection layer;
a light emitting layer on the hole transfer layer;
an electron transfer layer on the light emitting layer; and
an electron injection layer on the electron transfer layer, and
wherein the hole injection layer is partially disconnected.

11. The display device of claim 1, wherein
the anode electrode has an upper surface adjacent to the light emitting structure, and
the sacrificial pattern is along an edge of the anode electrode on the upper surface.

12. The display device of claim 11, wherein the light emitting structure is in contact with the upper surface of the anode electrode.

13. The display device of claim 1, wherein
the pixel definition layer further comprises a trench in the third portion and dented toward the substrate, and
the trench is around the anode electrode.

14. The display device of claim 1, wherein the pixel definition layer comprises:
a first insulating layer comprising the first portion, the second portion and the third portion;
a second insulating layer on the first insulating layer; and
a third insulating layer on the second insulating layer, and
wherein the third insulating layer has a width greater than a width of the second insulating layer.

15. A method of manufacturing a display device, the method comprising:
forming a pixel circuit layer on a substrate;
forming an anode electrode on the pixel circuit layer;
forming a metal layer on the anode electrode;
forming, on the pixel circuit layer, a pixel definition layer having an opening that exposes a part of the metal layer;
removing an exposed part of the metal layer and leaving, as a sacrificial pattern, another part of the metal layer which is not exposed, wherein the removing of the exposed part of the metal layer exposes at least a part of the anode electrode; and
forming a light emitting structure over the anode electrode and the pixel definition layer,
wherein the pixel definition layer comprises a first portion that overlaps the anode electrode and does not overlap the sacrificial pattern, a second portion that overlaps the anode electrode and the sacrificial pattern, and a third portion that does not overlap the anode electrode or the sacrificial pattern.

16. The method of claim 15, wherein, in the removing of the exposed part of the metal layer, the metal layer is wet-etched to form the first portion of the pixel definition layer protruding more than the sacrificial pattern.

17. The method of claim 15, wherein the light emitting structure is partially disconnected in a region adjacent to the first portion of the pixel definition layer.
